(19) United States
(12) Patent Application Publication
(10) Pub. No.: US 2024/0339453 A1
(43) Pub. Date: Oct. 10, 2024

(54) THREE-DIMENSIONAL SEMICONDUCTOR DEVICES AND METHODS OF FABRICATING THE SAME

(71) Applicant: Samsung Electronics Co., Ltd., Suwon-si (KR)

(72) Inventors: Hyojin Kim, Suwon-si (KR); Donghoon Hwang, Suwon-si (KR); Inchan Hwang, Suwon-si (KR)

(21) Appl. No.: 18/544,670

(22) Filed: Dec. 19, 2023

(30) Foreign Application Priority Data
Apr. 7, 2023 (KR) 10-2023-0045813

(51) Int. Cl. H01L 27/092; H01L 21/822; H01L 21/8238; H01L 23/528; H01L 29/06; H01L 29/417; H01L 29/423; H01L 29/66; H01L 29/775

(52) U.S. Cl. CPC H01L 27/0922; H01L 21/8221; H01L 21/823807; H01L 21/823814; H01L 21/823871; H01L 23/5286; H01L 29/0673; H01L 29/41733; H01L 29/42392; H01L 29/66439; H01L 29/66545; H01L 29/775

(57) ABSTRACT

A three-dimensional (3D) semiconductor device includes a substrate including a first surface and a second surface that are opposite to each other, a lower active region on the first surface of the substrate, the lower active region including a lower channel pattern and a lower source/drain pattern that are electrically connected to each other, an upper active region on the lower active region, the upper active region including an upper channel pattern and an upper source/drain pattern that are electrically connected to each other, a dam pattern that vertically extends from the lower source/drain pattern to the upper source/drain pattern, a lower active contact electrically connected to the lower source/drain pattern, an upper active contact electrically connected to the upper source/drain pattern, and a vertical via that vertically extends along the dam pattern to electrically connect the lower active contact to the upper active contact.

### CROSS-REFERENCE TO RELATED APPLICATION(S)

This U.S. non-provisional patent application claims priority under 35 U.S.C. § 119 to Korean Patent Application No. 10-2023-0045813, filed on Apr. 7, 2023, in the Korean Intellectual Property Office, the entire contents of which are hereby incorporated by reference.

### BACKGROUND

The present disclosure relates to three-dimensional semiconductor devices and methods of fabricating the same, and in particular, to three-dimensional semiconductor devices including a field effect transistor and methods of fabricating the same.

A semiconductor device can include an integrated circuit composed of metal-oxide-semiconductor field-effect transistors (MOSFETs). To meet an increasing demand for a semiconductor device with a small pattern size and a reduced design rule, the MOSFETs are being aggressively scaled down. The scale-down of the MOSFETs may lead to deterioration in operational properties of the semiconductor device. A variety of studies are being conducted to overcome technical limitations associated with the scale-down of the semiconductor device and to realize high-performance semiconductor devices.

### SUMMARY

Example embodiments of the inventive concepts provide three-dimensional semiconductor devices with an increased integration density and improved electrical characteristics.

Example embodiments of the inventive concepts provide methods of fabricating three-dimensional semiconductor devices with an increased integration density and improved electrical characteristics.

According to some embodiments of the inventive concepts, a three-dimensional (3D) semiconductor device may include a substrate including a first surface and a second surface that are opposite to each other, a lower active region on the first surface of the substrate, the lower active region including a lower channel pattern and a lower source/drain pattern that are electrically connected to each other, an upper active region on the lower active region, the upper active region including an upper channel pattern and an upper source/drain pattern that are electrically connected to each other, a dam pattern that vertically extends from the lower source/drain pattern to the upper source/drain pattern, a lower active contact electrically connected to the lower source/drain pattern, an upper active contact electrically connected to the upper source/drain pattern, and a vertical via that vertically extends along the dam pattern to electrically connect the lower active contact to the upper active contact. The dam pattern may include a first dam pattern and a second dam pattern. The lower source/drain pattern may be between the first and second dam patterns. The upper source/drain pattern may be between the first and second dam patterns.

According to some embodiments of the inventive concepts, a three-dimensional (3D) semiconductor device may include a substrate including a first surface and a second surface that are opposite to each other, logic cells arranged on the first surface of the substrate in a first direction, and a cutting pattern that is between adjacent ones of the logic cells and extends in a second direction crossing the first direction. Each of the logic cells may include a lower active region including a lower channel pattern and a lower source/drain pattern that are electrically connected to each other, an upper active region on the lower active region, the upper active region including an upper channel pattern and an upper source/drain pattern that are electrically connected to each other, and a gate electrode on the lower and upper channel patterns. At least a portion of the cutting pattern may extend in the second direction adjacent to the gate electrode. The cutting pattern may include a pair of dam patterns that vertically extend and an insulating gapfill layer that is between the pair of dam patterns.

According to some embodiments of the inventive concepts, a three-dimensional (3D) semiconductor device may include a lower active region on a logic cell of a substrate, the lower active region including a lower channel pattern and a lower source/drain pattern that are electrically connected to each other, an upper active region on the lower active region, the upper active region including an upper channel pattern and an upper source/drain pattern that are electrically connected to each other, a gate electrode on the lower channel pattern and the upper channel pattern, and a first cutting pattern and a second cutting pattern that define opposite borders of the logic cell. The gate electrode may be between the first and second cutting patterns. The lower and upper source/drain patterns may be between the first and second cutting patterns. The lower source/drain pattern may include a first side surface in contact with the first cutting pattern and a second side surface in contact with the second cutting pattern. A length of the first side surface may be different from a length of the second side surface.

### BRIEF DESCRIPTION OF THE DRAWINGS

FIG. 1 is a conceptual diagram illustrating a logic cell of a semiconductor device according to a comparative example.

FIG. 2 is a conceptual diagram illustrating a logic cell of a semiconductor device according to some embodiments of the inventive concepts.

FIG. 3 is a plan view illustrating a three-dimensional semiconductor device according to some embodiments of the inventive concepts.

FIGS. 4A, 4B, and 4C are sectional views respectively taken along lines A-A′, B-B′, and C-C′ of FIG. 3.

FIGS. 5A, 5B, 6A, 6B, 7A, 7B, 8A, 8B, 8C, 9A, 9B, 9C, 10A, 10B, 11A, 11B, 11C, 12A, 12B, 12C, 13A, 13B, 13C, 14A, 14B, and 14C are sectional views illustrating a method of fabricating a semiconductor device, according to some embodiments of the inventive concepts.

FIG. 15 is a sectional view, which is taken along a line B-B′ of FIG. 3 to illustrate a three-dimensional semiconductor device according to some embodiments of the inventive concepts.

FIGS. 16A and 16B are sectional views, which are respectively taken along lines B-B′ and C-C′ of FIG. 3 to illustrate a three-dimensional semiconductor device according to some embodiments of the inventive concepts.

### DETAILED DESCRIPTION

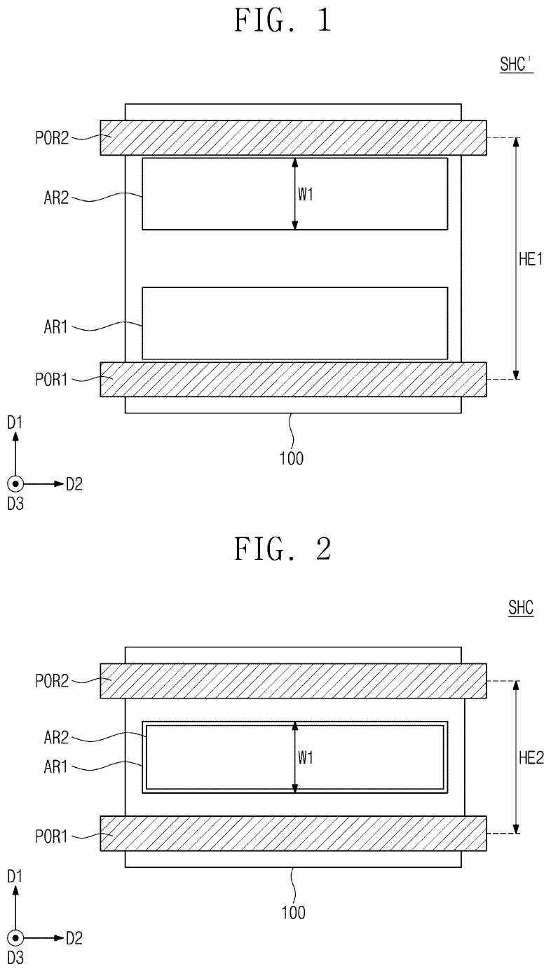

FIG. 1 is a conceptual diagram illustrating a logic cell of a semiconductor device according to a comparative example. FIG. 1 illustrates a logic cell of a two-dimensional device according to the comparative example.

Referring to FIG. 1, a single height cell SHC′ may be provided. In detail, a first power line POR1 and a second power line POR2 may be provided on a substrate 100. A drain voltage VDD (e.g., a power voltage) may be applied to one of the first and second power lines POR1 and POR2. A source voltage VSS (e.g., a ground voltage) may be applied to the other of the first and second power lines POR1 and POR2. In some embodiments, the source voltage VSS may be applied to the first power line POR1, and the drain voltage VDD may be applied to the second power line POR2.

The single height cell SHC′ may be defined between the first and second power lines POR1 and POR2. The single height cell SHC′ may include a first active region AR1 and a second active region AR2. One of the first and second active regions AR1 and AR2 may be a PMOSFET region, and the other of the first and second active regions AR1 and AR2 may be an NMOSFET region. For example, the first active region AR1 may be an NMOSFET region, and the second active region AR2 may be a PMOSFET region. That is, the single height cell SHC′ may include a CMOS structure that is provided between the first and second power lines POR1 and POR2.

The semiconductor device according to the comparative example may be a two-dimensional device, in which the transistors of the front-end-of-line (FEOL) layer are two-dimensionally arranged. For example, an NMOSFET of the first active region AR1 may be spaced apart from a PMOSFET of the second active region AR2 in a first direction D1.

Each of the first and second active regions AR1 and AR2 may have a first width W1 in the first direction D1. In the comparative example, a length of the single height cell SHC′ in the first direction D1 may be defined as a first height HE1. The first height HE1 may be substantially equal to a distance (e.g., pitch) between the first and second power lines POR1 and POR2.

The single height cell SHC′ may constitute a single logic cell. In the present specification, the logic cell may mean a logic device (e.g., AND, OR, XOR, XNOR, inverter, and so forth), which is configured to execute a specific function. In other words, the logic cell may include transistors constituting the logic device and interconnection lines connecting transistors to each other.

In the comparative example, since the single height cell SHC′ includes a two-dimensional device, the first and second active regions AR1 and AR2 may not be overlapped with each other (e.g., in a third direction D3) and may be spaced apart from each other in the first direction D1. Thus, the first height HE1 of the single height cell SHC′ should be defined to span both the first and second active regions AR1 and AR2, which are spaced apart from each other in the first direction D1. As a result, the first height HE1 of the single height cell SHC′ in the comparative example may have a relatively increased value. That is, the single height cell SHC′ in the comparative example may have a relatively large area.

FIG. 2 is a conceptual diagram illustrating a logic cell of a semiconductor device according to some embodiments of the inventive concepts. FIG. 2 illustrates a logic cell of a three-dimensional device according to some embodiments of the inventive concepts.

Referring to FIG. 2, a single height cell SHC, which includes a three-dimensional device with stacked transistors, may be provided. In detail, the first and second power lines POR1 and POR2 may be provided on the substrate 100. The single height cell SHC may be defined between the first power line POR1 and the second power line POR2.

The single height cell SHC may include the first and second active regions AR1 and AR2. One of the first and second active regions AR1 and AR2 may be a PMOSFET region, and the other of the first and second active regions AR1 and AR2 may be an NMOSFET region.

The semiconductor device may be a three-dimensional device, in which the transistors of the FEOL layer are vertically stacked (e.g., in a third direction D3). The first active region AR1 serving as a bottom tier may be provided on the substrate 100, and the second active region AR2 serving as a top tier may be stacked on the first active region AR1. For example, the NMOSFET of the first active region AR1 may be provided on the substrate 100, and the PMOSFET of the second active region AR2 may be stacked on the NMOSFET. The first and second active regions AR1 and AR2 may be spaced apart from each other in a vertical direction (e.g., in a third direction D3).

Each of the first and second active regions AR1 and AR2 may have a first width W1 in the first direction D1. A length of the single height cell SHC in the first direction D1 may be defined as a second height HE2.

Since the single height cell SHC includes the three-dimensional device (i.e., the stacked transistors), the first and second active regions AR1 and AR2 may be overlapped with each other (e.g., in a third direction D3). Thus, the second height HE2 of the single height cell SHC may have a size spanning a single active region or may be larger than the first width W1. As a result, the second height HE2 of the single height cell SHC may be smaller than the first height HE1 of the single height cell SHC′ of FIG. 1 described above. That is, the single height cell SHC may have a relatively small area. In the three-dimensional semiconductor device according to some embodiments, an integration density of the device may be increased by reducing an area of the logic cell. As used herein, “an element A overlapped with an element B in a direction X” (or similar language) means that there is at least one line that extends in the direction X and intersects both the elements A and B.

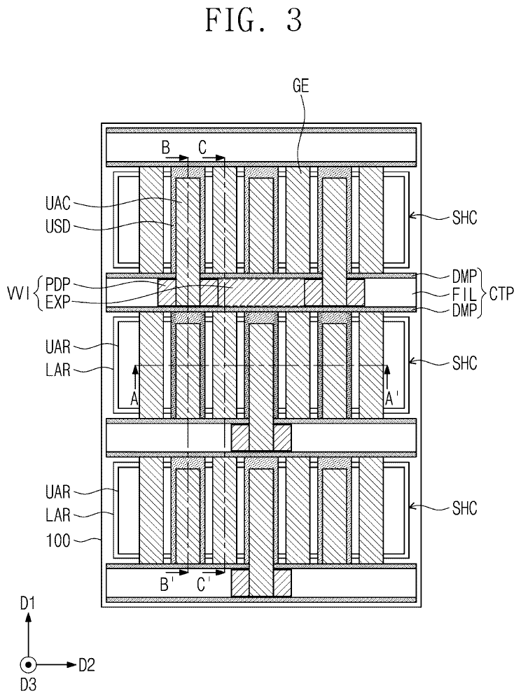

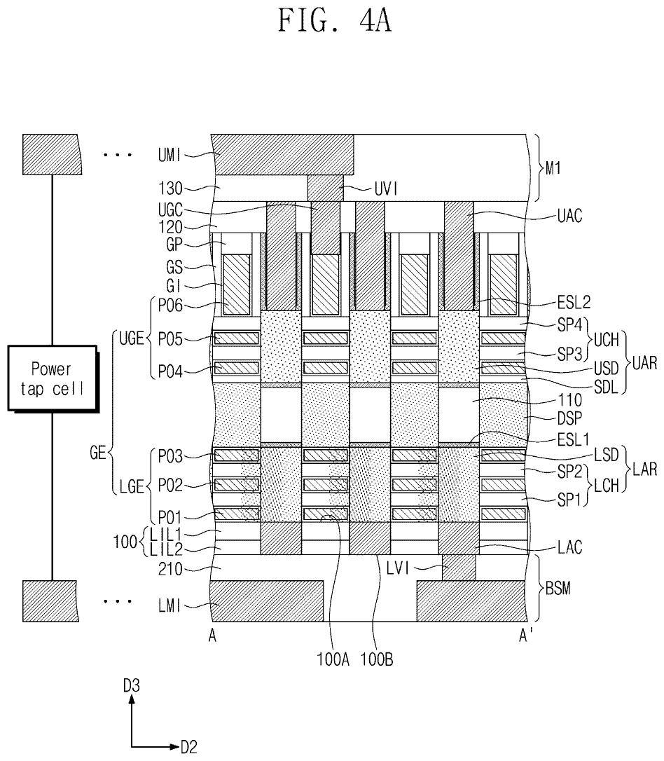

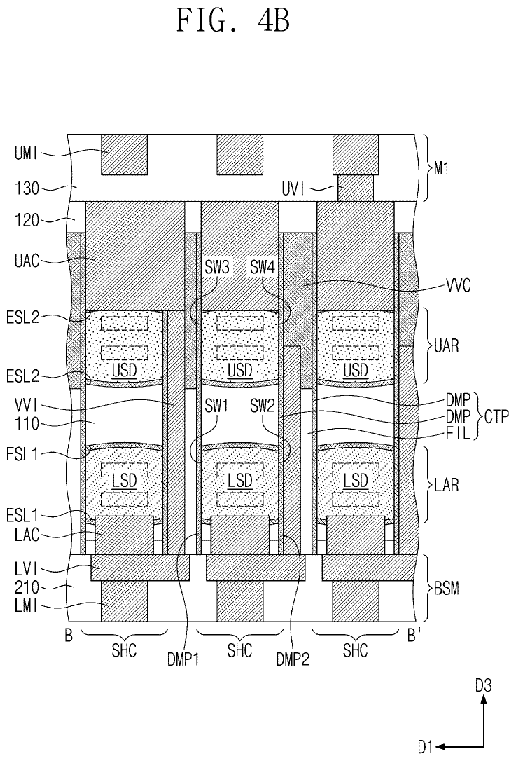

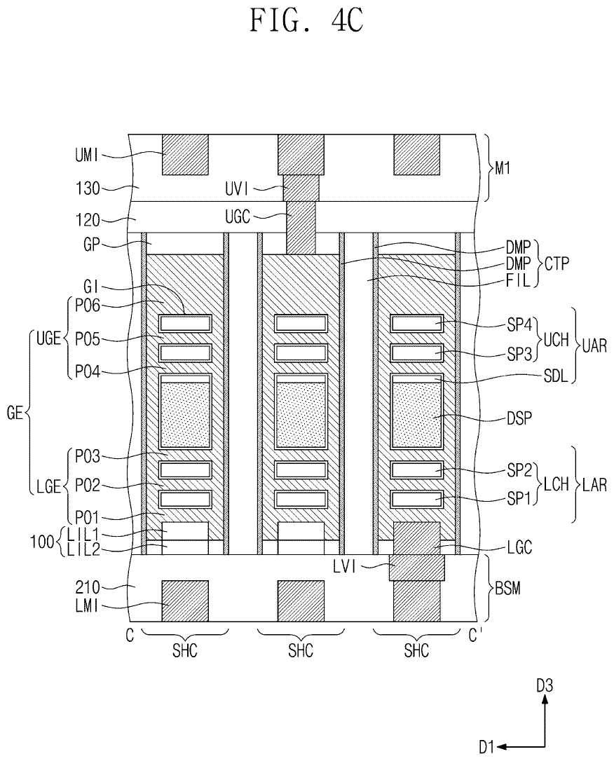

FIG. 3 is a plan view illustrating a three-dimensional semiconductor device according some embodiments of the inventive concepts. FIGS. 4A to 4C are sectional views respectively taken along lines A-A′, B-B′, and C-C′ of FIG. 3. The three-dimensional semiconductor device of FIGS. 3 and 4A to 4C may be a detailed example of the single height cell of FIG. 2.

Referring to FIGS. 3 and 4A to 4C, a single height cells SHC may be provided on the substrate 100. The substrate 100 may include a first surface 100A and a second surface 100B, which are opposite to each other. The first surface 100A may be the front surface of the substrate 100, and the second surface 100B may be the rear surface of the substrate 100. In some embodiments, the substrate 100 may be an insulating substrate, which is formed of or includes a silicon-based insulating material (e.g., silicon oxide and/or silicon nitride). In some embodiments, the substrate 100 may be a semiconductor substrate made of silicon, germanium, or silicon germanium.

In some embodiments, each of the single height cells SHC may be a logic cell constituting a logic circuit. Each of the single height cells SHC may be a logic cell, which includes a three-dimensional device previously described with reference to FIG. 2. The single height cells SHC may be arranged in the first direction D1. The single height cells SHC may be spaced apart from each other in the first direction D1.

Each of the single height cells SHC may include the lower and upper active regions LAR and UAR, which are sequentially stacked on the substrate 100. One of the lower and upper active regions LAR and UAR may be a PMOSFET region, and the other of the lower and upper active regions LAR and UAR may be an NMOSFET region. The lower active region LAR may be provided as a bottom tier of the FEOL layer, and the upper active region UAR may be provided as a top tier of the FEOL layer. The NMOSFET and PMOSFET of the lower and upper active regions LAR and UAR may be vertically stacked to constitute transistors, which are three-dimensionally stacked. In some embodiments, the lower active region LAR may be an NMOSFET region, and the upper active region UAR may be a PMOSFET region.

Each of the lower and upper active regions LAR and UAR may be a bar- or line-shaped region, which extends in a second direction D2. A cutting pattern CTP may be provided between the single height cells SHC, which are adjacent to each other. The cutting pattern CTP may separate adjacent ones of the single height cells SHC from each other. Adjacent ones of the single height cells SHC may be spaced apart from each other in the first direction D1 by the cutting pattern CTP. The cutting pattern CTP may be a bar- or line-shaped pattern extending in the second direction D2. The second direction D2 may cross the first direction D1.

The lower active region LAR including lower channel patterns LCH and lower source/drain patterns LSD may be provided on the single height cell SHC. The lower channel pattern LCH may be interposed between a pair of the lower source/drain patterns LSD. The pair of the lower source/drain patterns LSD may be adjacent to each other. The lower channel pattern LCH may connect the paired lower source/drain patterns LSD to each other.

The lower channel pattern LCH may include a first semiconductor pattern SP1 and a second semiconductor pattern SP2, which are stacked to be spaced apart from each other. Each of the first and second semiconductor patterns SP1 and SP2 may be formed of or include at least one of silicon (Si), germanium (Ge), or silicon germanium (SiGe). In some embodiments, each of the first and second semiconductor patterns SP1 and SP2 may be formed of or include crystalline silicon. Each of the first and second semiconductor patterns SP1 and SP2 may be a nanosheet.

The lower source/drain patterns LSD may be provided on the substrate 100. Each of the lower source/drain patterns LSD may be an epitaxial pattern, which is formed by a selective epitaxial growth (SEG) process. In some embodiments, a top surface of the lower source/drain pattern LSD may be higher than a top surface of the second semiconductor pattern SP2 of the lower channel pattern LCH. For example, a top surface of the lower source/drain pattern LSD may be higher than a top surface of the second semiconductor pattern SP2 of the lower channel pattern LCH with the first surface 100A of the substrate 100 providing a base reference plane.

The lower source/drain patterns LSD may be doped with impurities to have a first conductivity type. The first conductivity type may be an n- or p-type. In some embodiments, the first conductivity type may be an n-type. The lower source/drain patterns LSD may be formed of or include silicon (Si) and/or silicon germanium (SiGe).

A first etch stop layer ESL1 may be provided on the lower source/drain patterns LSD (e.g., see FIG. 4B). A first interlayer insulating layer 110 may be provided on the first etch stop layer ESL1. The first interlayer insulating layer 110 may cover the lower source/drain patterns LSD.

A lower active contact LAC may be provided below the lower source/drain pattern LSD. The lower active contact LAC may be electrically connected to the lower source/drain pattern LSD. The lower active contact LAC may be buried in the substrate 100. The lower active contact LAC may vertically extend from the second surface 100B of the substrate 100 to the first surface 100A. The lower active contact LAC may be formed of or include a metallic material that is selected from the group consisting of copper (Cu), aluminum (Al), ruthenium (Ru), cobalt (Co), tungsten (W), and molybdenum (Mo).

The upper active region UAR may be provided on the first interlayer insulating layer 110. The upper active region UAR may include upper channel patterns UCH and upper source/drain patterns USD. The upper channel patterns UCH may be vertically overlapped with the lower channel patterns LCH, respectively. The upper source/drain patterns USD may be vertically overlapped with the lower source/drain patterns LSD, respectively. The upper channel pattern UCH may be interposed between a pair of the upper source/drain patterns USD. The pair of the upper source/drain patterns USD may be adjacent to each other. The upper channel pattern UCH may connect the paired upper source/drain patterns USD to each other.

The upper channel pattern UCH may include a third semiconductor pattern SP3 and a fourth semiconductor pattern SP4, which are stacked to be spaced apart from each other. The third and fourth semiconductor patterns SP3 and SP4 of the upper channel pattern UCH may include the same semiconductor material as the first and second semiconductor patterns SP1 and SP2 of the lower channel pattern LCH. Each of the third and fourth semiconductor patterns SP3 and SP4 may be a nanosheet.

At least one dummy channel pattern DSP may be interposed between the lower channel pattern LCH and the upper channel pattern UCH thereon. A seed layer SDL may be interposed between the dummy channel pattern DSP and the upper channel pattern UCH.

The dummy channel pattern DSP may be spaced apart from the lower and upper source/drain patterns LSD and USD. In other words, the dummy channel pattern DSP may not be connected to any source/drain pattern. The dummy channel pattern DSP may be formed of or include at least one of semiconductor materials (e.g., silicon (Si), germanium (Ge), or silicon germanium (SiGe)) or silicon-based insulating materials (e.g., silicon oxide or silicon nitride). In some embodiments, the dummy channel pattern DSP may be formed of or include at least one of the silicon-based insulating materials.

The upper source/drain patterns USD may be provided on a top surface of the first interlayer insulating layer 110. Each of the upper source/drain patterns USD may be an epitaxial pattern, which is formed by a selective epitaxial growth (SEG) process. In some embodiments, a top surface of the upper source/drain pattern USD may be higher than a top surface of the fourth semiconductor pattern SP4 of the upper channel pattern UCH. For example, a top surface of the upper source/drain pattern USD may be higher than a top surface of the fourth semiconductor pattern SP4 of the upper channel pattern UCH with the first surface 100A of the substrate 100 providing a base reference plane.

The upper source/drain patterns USD may be doped with impurities to have a second conductivity type. The second conductivity type may be different from the first conductivity type of the lower source/drain pattern LSD. The second conductivity type may be a p-type. The upper source/drain patterns USD may be formed of or include at least one of silicon germanium (SiGe) and/or silicon (Si).

A second etch stop layer ESL2 may be provided on the upper source/drain patterns USD. In some embodiments, the second etch stop layer ESL2 may be interposed between the upper source/drain pattern USD and the first interlayer insulating layer 110.

A plurality of gate electrodes GE may be provided on the single height cell SHC. In detail, the gate electrode GE may be provided on the stacked lower and upper channel patterns LCH and UCH (e.g., see FIG. 4C). When viewed in a plan view, the gate electrode GE may be a bar-shaped pattern, which extends in the first direction D1. The gate electrode GE may be vertically overlapped with the stacked lower and upper channel patterns LCH and UCH.

The gate electrode GE may extend from the first surface 100A of the substrate 100 to a gate capping pattern GP in a vertical direction (i.e., the third direction D3). The gate electrode GE may extend from the lower channel pattern LCH of the lower active region LAR to the upper channel pattern UCH of the upper active region UAR in the third direction D3. The gate electrode GE may extend from the lowermost one of the first semiconductor patterns SP1 to the uppermost one of the fourth semiconductor patterns SP4 in the third direction D3.

The gate electrode GE may be provided on a top surface, a bottom surface, and opposite side surfaces of each of the first to fourth semiconductor patterns SP1 to SP4. That is, the transistor according to some embodiments may include a three-dimensional field effect transistor (e.g., a multi-bridge channel FET (MBCFET) or a gate-all-around FET (GAAFET)) in which the gate electrode GE is provided to three-dimensionally surround the channel pattern.

The gate electrode GE may include a lower gate electrode LGE, which is provided in the bottom tier of the FEOL layer (i.e., the lower active region LAR), and an upper gate electrode UGE, which is provided in the top tier of the FEOL layer (i.e., the upper active region UAR). The lower gate electrode LGE and the upper gate electrode UGE may be vertically overlapped with each other. In some embodiments, the lower gate electrode LGE and the upper gate electrode UGE may be connected to each other. That is, the gate electrode GE according to some embodiments may be a common gate electrode, in which the lower gate electrode LGE on the lower channel pattern LCH and the upper gate electrode UGE on the upper channel pattern UCH are connected to each other.

The lower gate electrode LGE may include a first inner electrode PO1 interposed between the substrate 100 and the first semiconductor pattern SP1, a second inner electrode PO2 interposed between the first semiconductor pattern SP1 and the second semiconductor pattern SP2, and a third inner electrode PO3 interposed between the second semiconductor pattern SP2 and the dummy channel pattern DSP.

The upper gate electrode UGE may include a fourth inner electrode PO4 interposed between the dummy channel pattern DSP (or the seed layer SDL) and the third semiconductor pattern SP3, a fifth inner electrode PO5 interposed between the third semiconductor pattern SP3 and the fourth semiconductor pattern SP4, and an outer electrode PO6 on the fourth semiconductor pattern SP4.

A pair of gate spacers GS may be disposed on opposite side surfaces of the gate electrode GE, respectively. Referring to FIG. 4A, the paired gate spacers GS may be disposed on opposite side surfaces of the outer electrode PO6, respectively. The gate spacers GS may extend along the gate electrode GE in the first direction D1. Top surfaces of the gate spacers GS may be higher than a top surface of the gate electrode GE. For example, top surfaces of the gate spacers GS may be higher than a top surface of the gate electrode GE with the first surface 100A of the substrate 100 providing a base reference plane. The top surfaces of the gate spacers GS may be coplanar with a top surface of a second interlayer insulating layer 120. The gate spacers GS may be formed of or include at least one of SiCN, SiCON, or SiN. In some embodiments, the gate spacers GS may be a multi-layered structure, which includes at least two different materials selected from SiCN, SiCON, and SiN.

The gate capping pattern GP may be provided on the top surface of the gate electrode GE. The gate capping pattern GP may extend along the gate electrode GE in the first direction D1. For example, the gate capping pattern GP may be formed of or include at least one of SiON, SiCN, SiCON, or SiN. The second etch stop layer ESL2 may be provided on the gate capping pattern GP and the gate spacer GS.

A gate insulating layer GI may be interposed between the gate electrode GE and the first to fourth semiconductor patterns SP1-SP4. The gate insulating layer GI may include a silicon oxide layer, a silicon oxynitride layer, and/or a high-k dielectric layer. In some embodiments, the gate insulating layer GI may include a silicon oxide layer, which is formed to directly cover a surface of the semiconductor pattern SP1-SP4, and a high-k dielectric layer, which is formed on the silicon oxide layer. In other words, the gate insulating layer GI may be a multi-layered structure including the silicon oxide layer and the high-k dielectric layer.

The high-k dielectric layer may be formed of or include at least one of high-k dielectric materials whose dielectric constants are higher than that of silicon oxide. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

The lower gate electrode LGE may include a first work function metal pattern on the first and second semiconductor patterns SP1 and SP2. The upper gate electrode UGE may include a second work function metal pattern on the third and fourth semiconductor patterns SP3 and SP4. Each of the first and second work function metal patterns may be formed of a material, which contains at least one metallic element, which is selected from the group consisting of titanium (Ti), tantalum (Ta), aluminum (Al), tungsten (W), molybdenum (Mo), and nitrogen (N). The first and second work function metal patterns may have different work functions from each other. The gate electrode GE may include at least one of low resistance metals (e.g., tungsten (W), ruthenium (Ru), aluminum (Al), titanium (Ti), or tantalum (Ta)) on the first and second work function metal patterns. For example, the outer electrode PO6 may include the second work function metal pattern as well as the low resistance metal.

The second interlayer insulating layer 120 may be provided on the upper source/drain patterns USD and the gate electrodes GE. The second interlayer insulating layer 120 may cover the upper source/drain patterns USD. A top surface of the second interlayer insulating layer 120 may be coplanar with a top surface of each of upper active contacts UAC, which will be described below.

The upper active contacts UAC may be provided to penetrate (i.e., extend in) the second interlayer insulating layer 120 and may be electrically connected to the upper source/drain patterns USD, respectively. In detail, the upper active contact UAC may be provided to penetrate the second interlayer insulating layer 120 and a second etch stop layer ELS2 and may be electrically connected to the upper source/drain pattern USD.

An upper gate contact UGC may be provided to penetrate the second interlayer insulating layer 120 and the gate capping pattern GP and may be electrically connected to the upper gate electrode UGE. Each of the upper active contact UAC and the upper gate contact UGC may be formed of or include a metallic material that is selected from the group consisting of copper (Cu), aluminum (Al), ruthenium (Ru), cobalt (Co), tungsten (W), and molybdenum (Mo).

The cutting pattern CTP may separate the gate electrodes GE, which are respectively disposed on adjacent ones of the single height cells SHC, from each other (e.g., see FIG. 4C). For example, the cutting pattern CTP may extend in the second direction D2 adjacent to the gate electrodes GE, and the gate electrodes GE on adjacent ones of the single height cells SHC may be separated from each other. The cutting pattern CTP may separate the upper source/drain patterns USD, which are respectively disposed on different ones of the single height cells SHC, from each other (e.g., see FIG. 4B). The cutting pattern CTP may separate the lower source/drain patterns LSD, which are respectively disposed on different ones of the single height cells SHC, from each other (e.g., see FIG. 4B).

The cutting pattern CTP may include a pair of dam patterns DMP and an insulating gapfill layer FIL between the dam patterns DMP. The paired dam patterns DMP may extend in the second direction D2 parallel to each other (e.g., see FIG. 3). The dam pattern DMP may be formed of or include at least one of SiCN, SiCON, or SiN. The insulating gapfill layer FIL may include a silicon oxide layer.

Referring back to FIG. 4B, a pair of cutting patterns CTP may be provided at both sides of the single height cell SHC. That is, the single height cell SHC may be interposed between the paired cutting patterns CTP. A first dam pattern DMP1 and a second dam pattern DMP2 may be respectively provided at both sides of the single height cell SHC.

Each of the first and second dam patterns DMP1 and DMP2 may extend in a vertical direction (i.e., the third direction D3). The second height HE2 of the single height cell SHC previously described with reference to FIG. 2 may be defined by the first and second dam patterns DMP1 and DMP2. That is, a distance between the first and second dam patterns DMP1 and DMP2 in the first direction D1 may correspond to the second height HE2.

The lower source/drain pattern LSD may be sandwiched between the first and second dam patterns DMP1 and DMP2. The upper source/drain pattern USD may be sandwiched between the first and second dam patterns DMP1 and DMP2. The lower source/drain pattern LSD may include first and second side surfaces SW1 and SW2, which are opposite to each other in the first direction D1. The first side surface SW1 may be in direct contact with the first dam pattern DMP1, and the second side surface SW2 may be in direct contact with the second dam pattern DMP2.

Each of the first and second side surfaces SW1 and SW2 may have a profile, which vertically extends in the third direction D3. In some embodiments, each of the first and second side surfaces SW1 and SW2 may be a plane that is normal to the first direction D1.

A width of the lower source/drain pattern LSD in the first direction D1 may be substantially equal to a distance between the first and second side surfaces SW1 and SW2. The width of the lower source/drain pattern LSD in the first direction D1 may be substantially equal to the distance between the first and second dam patterns DMP1 and DMP2.

The upper source/drain pattern USD may include third and fourth side surfaces SW3 and SW4, which are opposite to each other in the first direction D1. The third side surface SW3 may be in direct contact with the first dam pattern DMP1, and the fourth side surface SW4 may be in direct contact with the second dam pattern DMP2. The third side surface SW3 may be aligned to the first side surface SW1 in the third direction D3, and the fourth side surface SW4 may be aligned to the second side surface SW2 in the third direction D3.

Each of the third and fourth side surfaces SW3 and SW4 may have a profile, which vertically extends in the third direction D3. In some embodiments, each of the third and fourth side surfaces SW3 and SW4 may be a plane that is normal to the first direction D1.

A width of the upper source/drain pattern USD in the first direction D1 may be substantially equal to a distance between the third and fourth side surfaces SW3 and SW4. The width of the upper source/drain pattern USD in the first direction D1 may be substantially equal to the distance between the first and second dam patterns DMP1 and DMP2. The width of the upper source/drain pattern USD in the first direction D1 may be substantially equal to the width of the lower source/drain pattern LSD in the first direction D1.

According to some embodiments of the inventive concepts, the first and second dam patterns DMP1 and DMP2 may clearly define a border of the single height cell SHC.

Accordingly, the first and second dam patterns DMP1 and DMP2 may prevent the lower and upper source/drain patterns LSD and USD from being horizontally expanded to other single height cell(s) SHC. The first and second dam patterns DMP1 and DMP2 may prevent the lower and upper source/drain patterns LSD and USD from being expanded to a vertical via VVI, which is buried in the cutting pattern CTP.

Referring back to FIGS. 3 and 4A to 4C, the vertical via VVI may be provided in the cutting pattern CTP. When viewed in a plan view, the vertical via VVI may be a bar-shaped pattern extending in the second direction D2. The vertical via VVI may vertically extend along the dam pattern DMP and in the third direction D3. The vertical via VVI may extend from a back-side metal layer BSM, which will be described below, to the upper active contact UAC. The vertical via VVI may be configured to connect the lower source/drain pattern LSD to the upper source/drain pattern USD vertically and electrically.

The vertical vias VVI may be buried in the insulating gapfill layer FIL. The vertical vias VVI may have different heights from each other, as illustrated in FIG. 4B. If it is necessary to electrically connect the lower and upper source/drain patterns LSD and USD to each other, the vertical via VVI may be in direct contact with the upper active contact UAC. If it is unnecessary to connect the lower and upper source/drain patterns LSD and USD to each other, the vertical via VVI may not extend to the upper active contact UAC.

A contact capping pattern VVC may be provided on the vertical via VVI. The contact capping pattern VVC may cover a top surface and an upper side surface of the vertical via VVI. The contact capping pattern VVC may cover a top surface of the insulating gapfill layer FIL. A top surface of the contact capping pattern VVC may be coplanar with top surfaces of the dam patterns DMP.

Referring back to FIG. 3, the vertical via VVI may be fully overlapped with the cutting pattern CTP. In some embodiments, at least one of the vertical vias VVI may extend in the second direction D2 by a length longer than a gate pitch. The vertical via VVI may include a horizontally extended portion EXP and a pad portion PDP. The horizontally extended portion EXP may have a top surface that is lower than the top surface of the upper source/drain pattern USD. For example, the horizontally extended portion EXP may have a top surface that is lower than the top surface of the upper source/drain pattern USD with the first surface 100A of the substrate 100 providing a base reference plane. The horizontally extended portion EXP may be a bar- or line-shaped pattern extending in the second direction D2. The pad portion PDP may vertically extend from the horizontally extended portion EXP to be in contact with the upper active contact UAC.

Referring back to FIGS. 3 and 4A to 4C, a third interlayer insulating layer 130 may be provided on the second interlayer insulating layer 120. A first metal layer M1 may be provided in the third interlayer insulating layer 130. The first metal layer M1 may include upper interconnection lines UMI. The first metal layer M1 may further include an upper via UVI. The upper via UVI may be provided to electrically connect one of the upper active contact UAC and the upper gate contact UGC to the upper interconnection line UMI. Each of the upper interconnection line UMI and the upper via UVI may be formed of or include a metallic material that is selected from the group consisting of copper (Cu), aluminum (Al), ruthenium (Ru), cobalt (Co), tungsten (W), and molybdenum (Mo).

Additional metal layers (e.g., M2, M3, M4, and so forth) may be stacked on the first metal layer M1. The first metal layer M1 and the additional metal layers (e.g., M2, M3, M4, and so forth) thereon may constitute a back-end-of-line (BEOL) layer of the semiconductor device. The additional metal layers (e.g., M2, M3, M4, and so forth) on the first metal layer M1 may include routing lines, which are used to connect the logic cells to each other.

A lower interlayer insulating layer 210 may be provided below the second surface 100B of the substrate 100. The back-side metal layer BSM may be provided in the lower interlayer insulating layer 210. The back-side metal layer BSM may include lower interconnection lines LMI. The back-side metal layer BSM may further include a lower via LVI. The lower via LVI may be provided to electrically connect one of the lower active contact LAC and the lower gate contact LGC to the lower interconnection line LMI.

Each of the lower interconnection line LMI and the lower via LVI may be formed of or include a metallic material that is selected from the group consisting of copper (Cu), aluminum (Al), ruthenium (Ru), cobalt (Co), tungsten (W), and molybdenum (Mo).

Lower metal layers may be further stacked below the back-side metal layer BSM. In some embodiments, the lower metal layers may include a power delivery network. The power delivery network may include a wiring network, which is used to apply the source and drain voltages VSS and VDD to the back-side metal layer BSM.

The source and drain voltages VSS and VDD may be applied to the back-side metal layer BSM through the power delivery network. Referring back to FIG. 4A, one of the source and drain voltages VSS and VDD may be applied to the lower source/drain pattern LSD through the lower interconnection line LMI, the lower via LVI, and the lower active contact LAC. The other of the source and drain voltages VSS and VDD may be applied from the back-side metal layer BSM to the first metal layer M1 through a power tap cell. A voltage, which is applied to the first metal layer M1 through the power tap cell, may be applied to the upper source/drain pattern USD through the upper interconnection line UMI, the upper via UVI, and the upper active contact UAC. The power tap cell may be interposed between the single height cells SHC, which are adjacent to each other.

According to some embodiments of the inventive concepts, a pair of the cutting patterns CTP may be used to define the single height cell SHC. Due to the paired cutting patterns CTP, it may be possible to prevent the lower and upper source/drain patterns LSD and USD from being horizontally expanded to a region beyond each cell. Since the vertical via VVI is provided in the cutting pattern CTP, it may be possible to effectively prevent a short circuit issue between the vertical via VVI and the lower and upper source/drain patterns LSD and USD. As a result, a process defect may be prevented to improve the reliability characteristics of the three-dimensional semiconductor device, and a cell height may be reduced to increase an integration density of the three-dimensional semiconductor device.

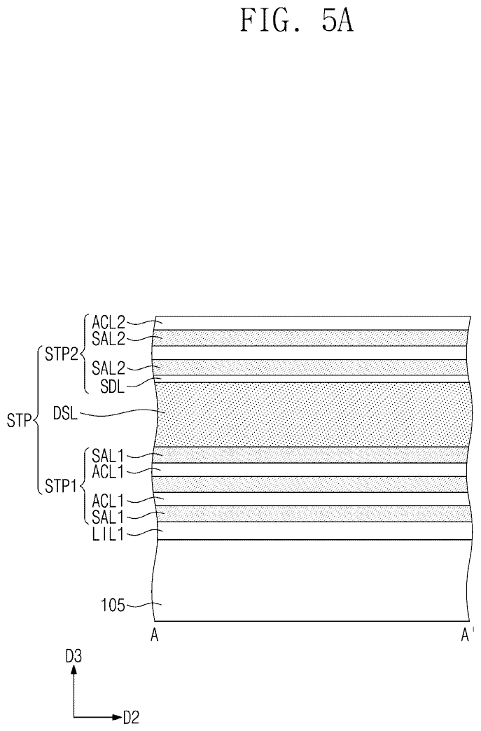

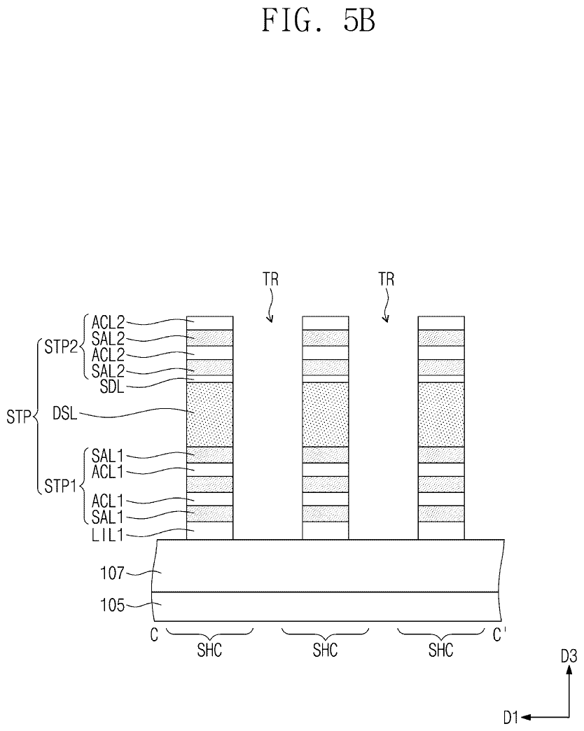

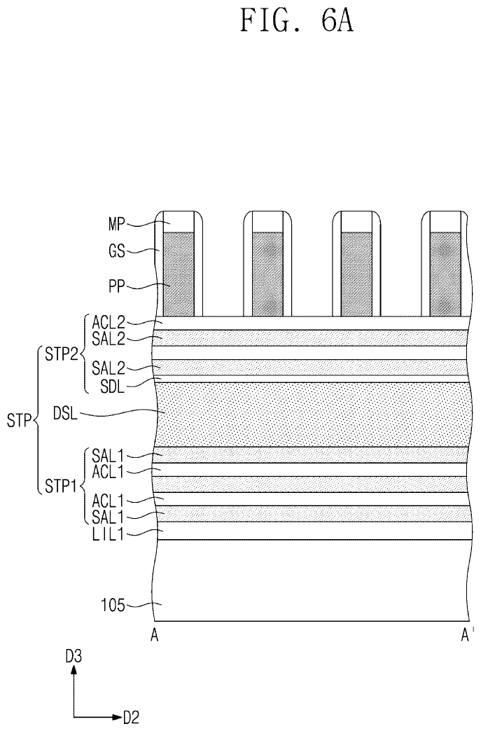

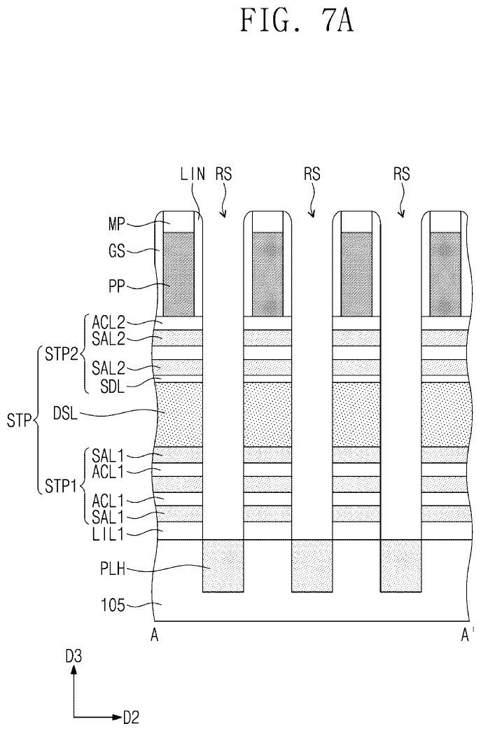

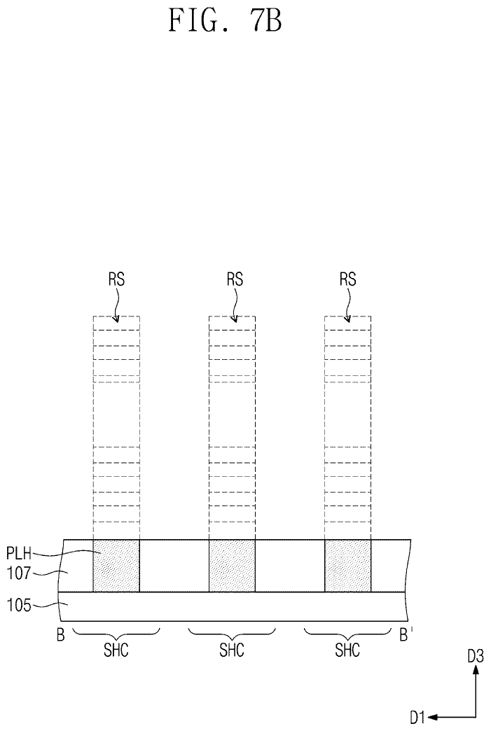

FIGS. 5A to 14C are sectional views illustrating a method of fabricating a semiconductor device, according to some embodiments of the inventive concepts. In detail, FIGS. 5A, 6A, 7A, 8A, 9A, 10A, 11A, 12A, 13A, and 14A are sectional views corresponding to the line A-A′ of FIG. 3. FIGS. 7B, 8B, 9B, 10B, 11B, 12B, 13B, and 14B are sectional views corresponding to the line B-B′ of FIG. 3. FIGS. 5B, 6B, 8C, 9C, 11C, 12C, 13C, and 14C are sectional views corresponding to the line C-C′ of FIG. 3.

Referring to FIGS. 5A and 5B, a semiconductor substrate 105 may be provided. The semiconductor substrate 105 may be formed of or include at least one of silicon (Si), germanium (Ge), or silicon-germanium (SiGe). For example, the semiconductor substrate 105 may be a single crystalline silicon wafer.

A first lower insulating layer LIL1 may be formed on the semiconductor substrate 105. The first lower insulating layer LIL1 may be formed of or include at least one of silicon-based insulating materials (e.g., silicon oxide) and/or semiconductor materials (e.g., Si or SiGe).

First sacrificial layers SAL1 and first active layers ACL1 may be alternately formed on the first lower insulating layer LIL1. The first sacrificial layers SAL1 and the first active layers ACL1 may be formed of or include at least one of silicon (Si), germanium (Ge), or silicon germanium (SiGe) and may be formed of different materials from each other. For example, the first sacrificial layers SAL1 may be formed of or include silicon germanium (SiGe), and the first active layers ACL1 may be formed of or include silicon (Si). A concentration of germanium (Ge) in each of the first sacrificial layers SAL1 may range from 10 at % to 30 at %.

A separation layer DSL may be formed on the uppermost one of the first sacrificial layers SAL1. In some embodiments, a thickness of the separation layer DSL (e.g., in a third direction D3) may be larger than a thickness of the first sacrificial layer SAL1. The separation layer DSL may be formed of or include silicon (Si) or silicon germanium (SiGe). In the case where the separation layer DSL includes silicon germanium (SiGe), a germanium concentration of the separation layer DSL may be higher than a germanium concentration of the first sacrificial layer SAL1. For example, the germanium concentration of the separation layer DSL may range from 40 at % to 90 at %.

The seed layer SDL may be formed on the separation layer DSL. The seed layer SDL may be formed of or include the same the material as the first active layer ACL1. Second sacrificial layers SAL2 and second active layers ACL2 may be alternately stacked on the seed layer SDL. Each of the second sacrificial layers SAL2 may be formed of or include the same material as the first sacrificial layer SAL1, and each of the second active layers ACL2 may be formed of or include the same material as the first active layer ACL1. The separation layer DSL may be interposed between the first sacrificial layer SAL1 and the seed layer SDL.

A stacking pattern STP may be formed by patterning the first and second sacrificial layers SAL1 and SAL2, the first and second active layers ACL1 and ACL2, and the separation layer DSL which are stacked. The formation of the stacking pattern STP may include forming a hard mask pattern on the uppermost one of the second active layers ACL2, and etching the layers SAL1, SAL2, ACL1, ACL2, SDL, and DSL, which are stacked on the semiconductor substrate 105, using the hard mask pattern as an etch mask. During the formation of the stacking pattern STP, the layers SAL1, SAL2, ACL1, ACL2, SDL, and DSL on the semiconductor substrate 105 may be patterned to form a trench TR defining the single height cell SHC. The stacking pattern STP may be a bar- or line-shaped pattern extending in the second direction D2.

The stacking pattern STP may include a lower stacking pattern STP1 on the first lower insulating layer LIL1, an upper stacking pattern STP2 on the lower stacking pattern STP1, and the separation layer DSL between the lower and upper stacking patterns STP1 and STP2. The lower stacking pattern STP1 may include the first sacrificial layers SAL1 and the first active layers ACL1 which are alternately stacked. The upper stacking pattern STP2 may include the seed layer SDL and the second sacrificial and active layers SAL2 and ACL2, which are alternatingly stacked on the seed layer SDL.

A device isolation layer 107 may be formed on the semiconductor substrate 105 to fill the trench TR. In detail, an insulating layer may be formed on the semiconductor substrate 105 to cover the stacking patterns STP. The device isolation layer 107 may be formed by recessing the insulating layer to expose the stacking patterns STP.

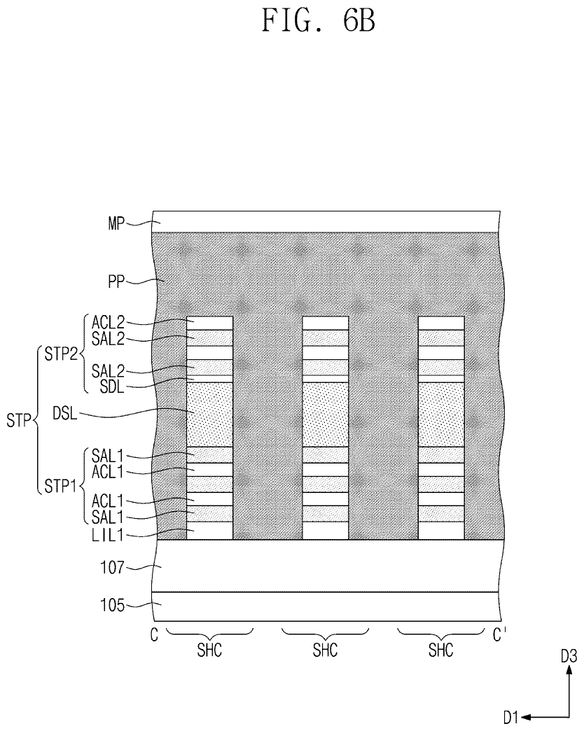

Referring to FIGS. 6A and 6B, a plurality of sacrificial patterns PP may be formed to cross the stacking pattern STP. Each of the sacrificial patterns PP may be formed to have a line shape extending in the first direction D1. In detail, the formation of the sacrificial pattern PP may include forming a sacrificial layer on the semiconductor substrate 105, forming a hard mask pattern MP on the sacrificial layer, and patterning the sacrificial layer using the hard mask pattern MP as an etch mask. The sacrificial layer may be formed of or include amorphous silicon and/or polysilicon.

A pair of the gate spacers GS may be formed on opposite side surfaces of the sacrificial pattern PP, respectively. In detail, a spacer layer may be conformally formed on the semiconductor substrate 105. The spacer layer may cover the sacrificial pattern PP and the hard mask pattern MP. For example, the spacer layer may be formed of or include at least one of SiCN, SiCON, or SiN. The gate spacers GS may be formed by anisotropically etching the spacer layer.

Referring to FIGS. 7A and 7B, an etching process may be performed on the stacking pattern STP using the gate spacers GS and the hard mask pattern MP as an etch mask. As a result of the etching process, a recess RS may be formed between adjacent ones of the sacrificial patterns PP. Due to the recess RS, the stacking pattern STP may be formed to have a stick shape.

Sacrificial contact patterns PLH may be formed in the semiconductor substrate 105 exposed through the recess RS. The sacrificial contact patterns PLH may be formed in the form of a contact plug. The sacrificial contact patterns PLH may be arranged in the second direction D2. The sacrificial contact patterns PLH may be formed of or include a material (e.g., silicon-germanium (SiGe)) having an etch selectivity with respect to the semiconductor substrate 105. The sacrificial contact patterns PLH may be formed by an epitaxial growth process. The recess RS may be formed to expose the sacrificial contact pattern PLH. That is, the recess RS may be overlapped with the sacrificial contact pattern PLH (e.g., in the third direction D3).

In the case where the separation layer DSL includes silicon germanium (SiGe), the separation layer DSL may be replaced with a silicon-based insulating material. For example, the separation layer DSL, which is exposed through the recess RS, may be selectively removed to form an empty region, and then, a silicon-based insulating material (e.g., silicon nitride) may be formed to fill the empty region.

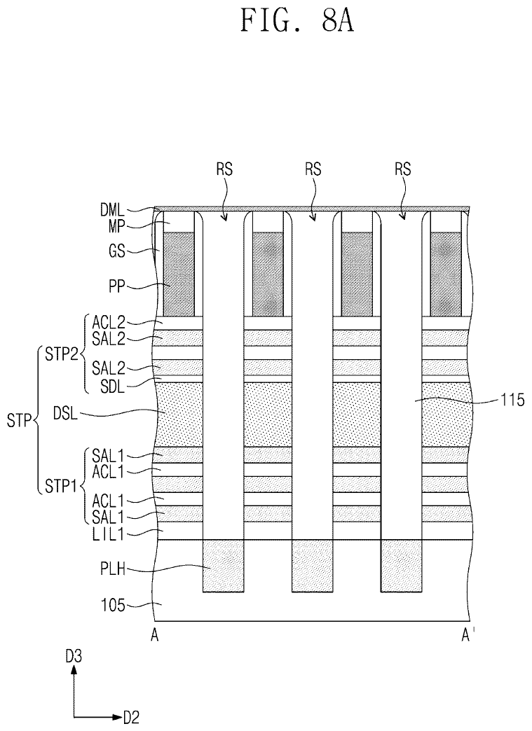

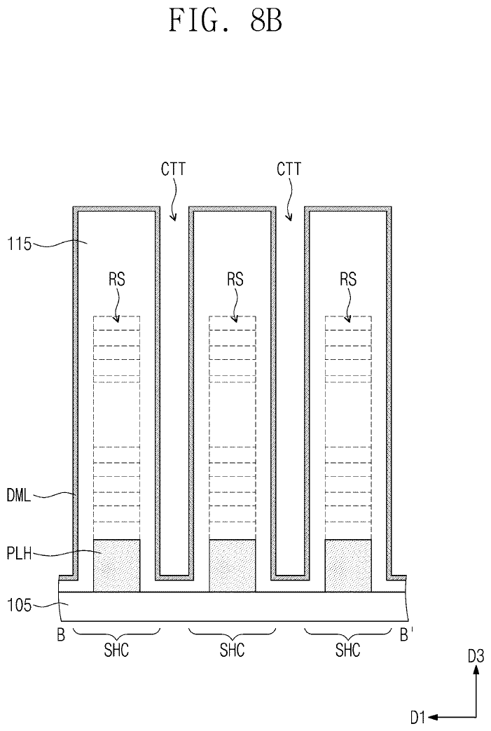

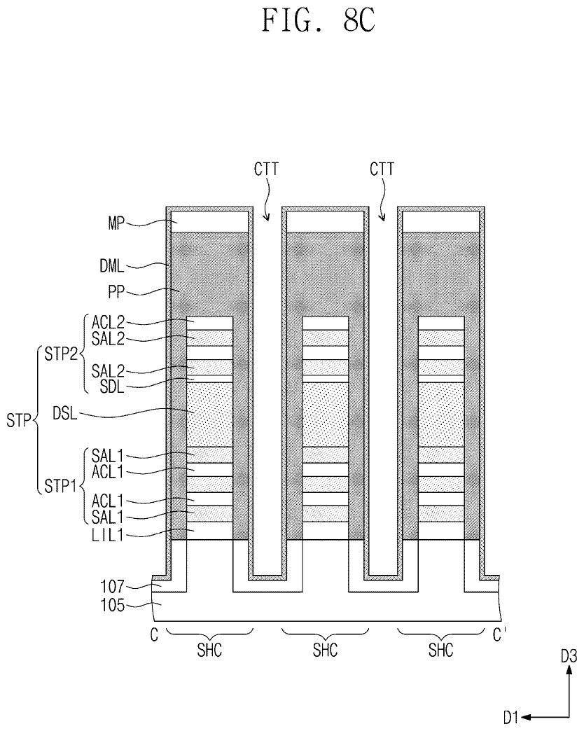

Referring to FIGS. 8A to 8C, a preliminary interlayer insulating layer 115 may be formed on the semiconductor substrate 105. The preliminary interlayer insulating layer 115 may be formed to fill all of the recesses RS and the trenches TR. The preliminary interlayer insulating layer 115 may cover the stacking pattern STP and the sacrificial pattern PP.

A cutting trench CTT may be formed between adjacent ones of the single height cells SHC. The formation of the cutting trench CTT may include forming a mask layer to open (i.e., expose) a region between adjacent ones of the single height cells SHC and anisotropically etching the preliminary interlayer insulating layer 115 and the sacrificial pattern PP using the mask layer as an etch mask.

The cutting trench CTT may be a line-shaped region that extends in the second direction D2. The cutting trench CTT may be formed to cut the sacrificial pattern PP. The cutting trench CTT may be formed to have a bottom that is lower than a top surface of the sacrificial contact pattern PLH.

A fence layer DML may be conformally formed on an inner surface of the cutting trench CTT. The fence layer DML may be formed along a profile of the cutting trench CTT. The fence layer DML may directly cover the preliminary interlayer insulating layer 115 (e.g., see FIG. 8B). The fence layer DML may directly cover the sacrificial pattern PP (e.g., see FIG. 8C). The fence layer DML may be formed of or include at least one of SiCN, SiCON, or SiN. For example, the fence layer DML may include a silicon nitride layer.

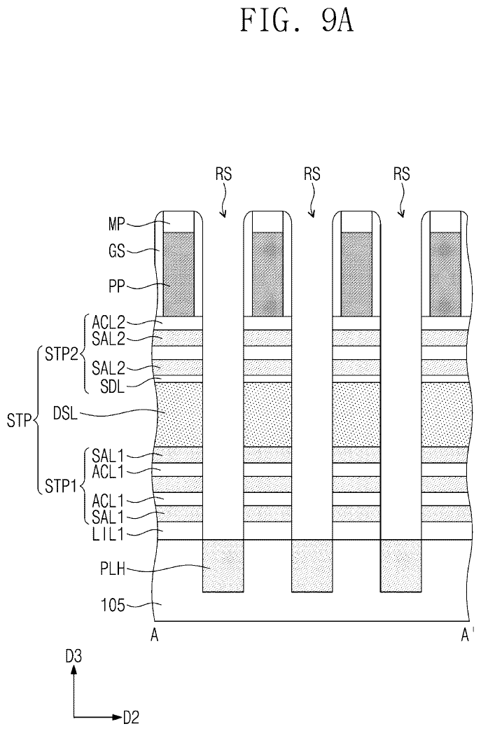

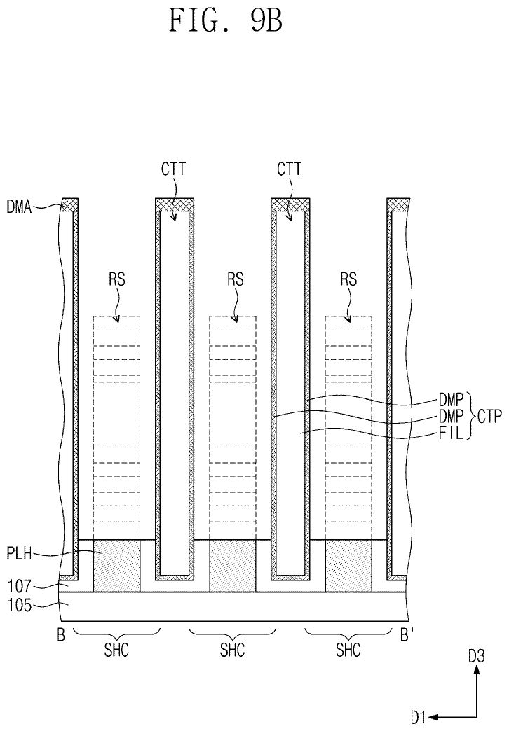

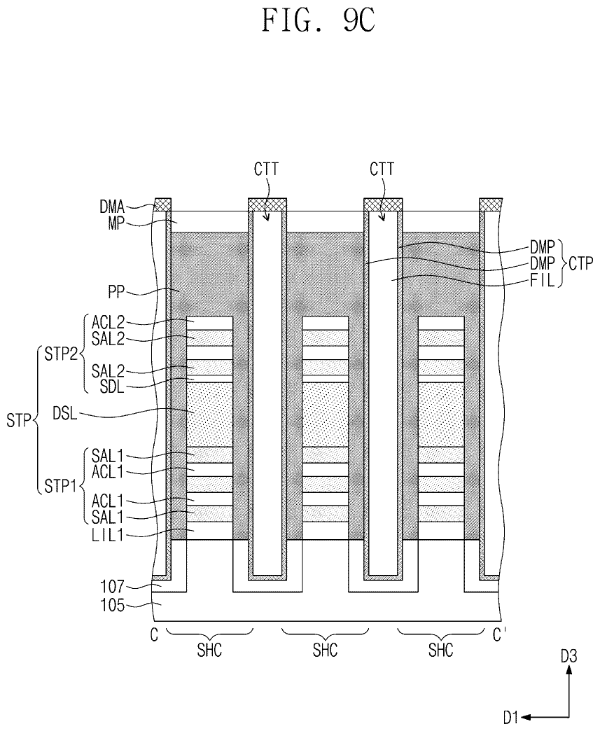

Referring to FIGS. 9A to 9C, the insulating gapfill layer FIL may be formed on the fence layer DML to fill the cutting trench CTT. When viewed in a plan view, the insulating gapfill layer FIL may be a line-shaped pattern, which extends along the cutting trench CTT in the second direction D2. The insulating gapfill layer FIL may be formed between adjacent ones of the single height cells SHC.

A cutting mask layer DMA may be formed on the insulating gapfill layer FIL. The cutting mask layer DMA may be vertically overlapped with the insulating gapfill layer FIL. The cutting mask layer DMA may be vertically overlapped with the fence layer DML on the inner surface of the cutting trench CTT.

The preliminary interlayer insulating layer 115 may be etched using the cutting mask layer DMA as an etch mask. Accordingly, the preliminary interlayer insulating layer 115 may be fully removed. Since the preliminary interlayer insulating layer 115 is removed, the recess RS may be exposed again. Meanwhile, the sacrificial pattern PP may be protected by the hard mask pattern MP during the etching process.

The cutting pattern CTP may be formed by the etching process. The cutting pattern CTP may be overlapped with the cutting trench CTT. Between adjacent ones of the single height cells SHC, the cutting pattern CTP may extend in the second direction D2. The cutting pattern CTP may include the insulating gapfill layer FIL and a pair of the dam patterns DMP, which are provided on opposite side surfaces of the insulating gapfill layer FIL. The dam patterns DMP may be formed from a remaining portion of the fence layer DML. The cutting pattern CTP may define a boundary between the single height cells SHC.

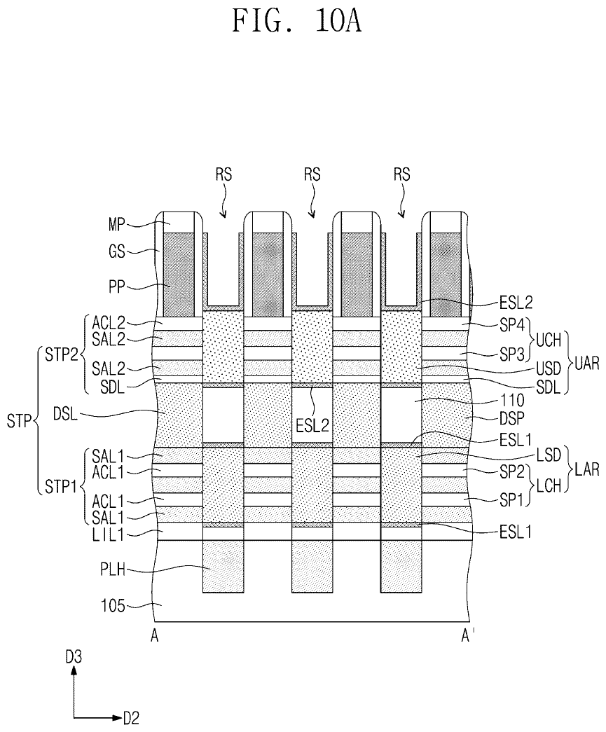

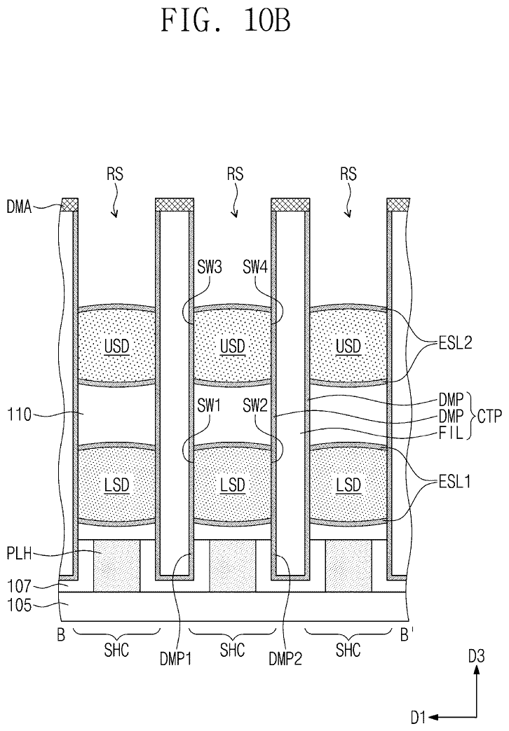

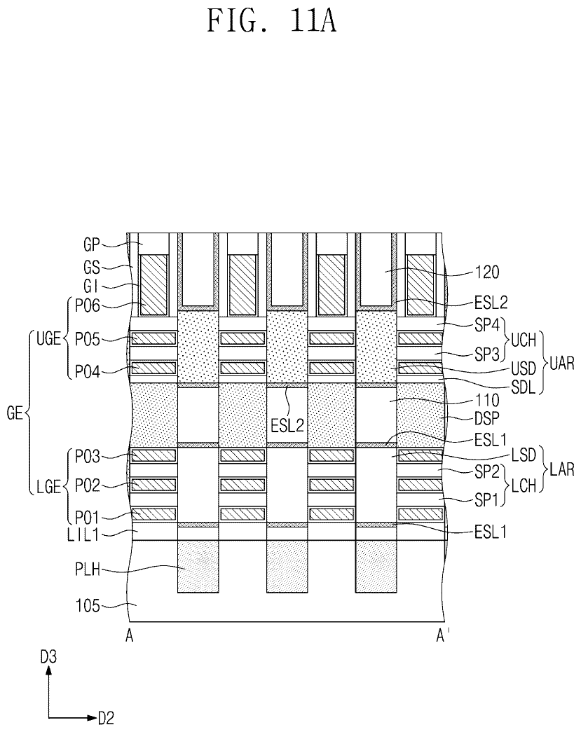

Referring to FIGS. 10A and 10B, the recess RS may be exposed between the cutting patterns CTP, which are adjacent to each other. The lower source/drain pattern LSD may be formed in the recess RS. In detail, the lower source/drain pattern LSD may be formed by performing a first SEG process using a side surface of the lower stacking pattern STP1, which is exposed through the recess RS, as a seed layer. The lower source/drain pattern LSD may be grown using the first active layers ACL1, which are exposed through a first recess (e.g., adjacent to the first active layers ACL1), as a seed layer. As an example, the first SEG process may include a chemical vapor deposition (CVD) process or a molecular beam epitaxy (MBE) process.

As an example, impurities may be injected into the lower source/drain pattern LSD in an in-situ manner during the first SEG process. As another example, impurities may be injected into the lower source/drain pattern LSD, after the formation of the lower source/drain pattern LSD. The lower source/drain pattern LSD may be doped to have a first conductivity type (e.g., an n-type).

Referring back to FIG. 10A, the first active layers ACL1, which are interposed between the paired lower source/drain patterns LSD, may constitute the lower channel pattern LCH. That is, the first and second semiconductor patterns SP1 and SP2 of the lower channel pattern LCH may be formed from the first active layers ACL1. The lower channel patterns LCH and the lower source/drain patterns LSD may constitute the lower active region LAR serving as the bottom tier of the three-dimensional device.

The lower source/drain pattern LSD may be formed to fully fill a space between a pair of the lower channel patterns LCH. That is, the first SEG process may be performed for a sufficient time until the lower source/drain pattern LSD is grown to fill a space between the paired lower channel patterns LCH and connect the paired lower channel patterns LCH to each other.

Referring back to FIG. 10B, the lower source/drain pattern LSD may be grown in a horizontal direction, which is parallel to the first direction D1, during the first SEG process. In some embodiments, the first dam pattern DMP1 and the second dam pattern DMP2 may be respectively formed at both sides of the single height cell SHC. The first and second dam patterns DMP1 and DMP2 may prevent the lower source/drain pattern LSD from being horizontally grown in the first direction D1. That is, the horizontal expansion of the lower source/drain pattern LSD may be restricted by the first and second dam patterns DMP1 and DMP2. As a result, the lower source/drain pattern LSD may not be expanded to an outer region beyond the single height cell SHC and may be locally formed in only the single height cell SHC.

Referring back to FIGS. 10A and 10B, the first etch stop layer ESL1 may be conformally formed on the lower source/drain pattern LSD. The first interlayer insulating layer 110 may be formed on the first etch stop layer ESL1.

The first interlayer insulating layer 110 may be recessed to expose a side surface of the upper stacking pattern STP2 through the recess RS. The upper source/drain pattern USD may be formed in the recess RS. In detail, the upper source/drain pattern USD may be formed by performing a second SEG process using the side surface of the upper stacking pattern STP2, which is exposed by the recess RS, as a seed layer. The upper source/drain pattern USD may be grown using the second active layers ACL2, which are exposed through the recess RS, as a seed layer. The upper source/drain pattern USD may be doped to have the second conductivity type (e.g., p-type), which is different from the first conductivity type.

The second active layers ACL2, which are interposed between the paired upper source/drain patterns USD, may constitute the upper channel pattern UCH. That is, the third and fourth semiconductor patterns SP3 and SP4 of the upper channel pattern UCH may be formed from the second active layers ACL2. The upper channel patterns UCH and the upper source/drain patterns USD may constitute the upper active region UAR serving as the top tier of the three-dimensional device. The second etch stop layer ESL2 may be conformally formed on the upper source/drain pattern USD.

The second SEG process may also be performed for a sufficient time until the upper source/drain pattern USD is grown to fully fill a space between the paired upper channel patterns UCH. The first and second dam patterns DMP1 and DMP2 may prevent the upper source/drain pattern USD from being horizontally grown outside the single height cell SHC.

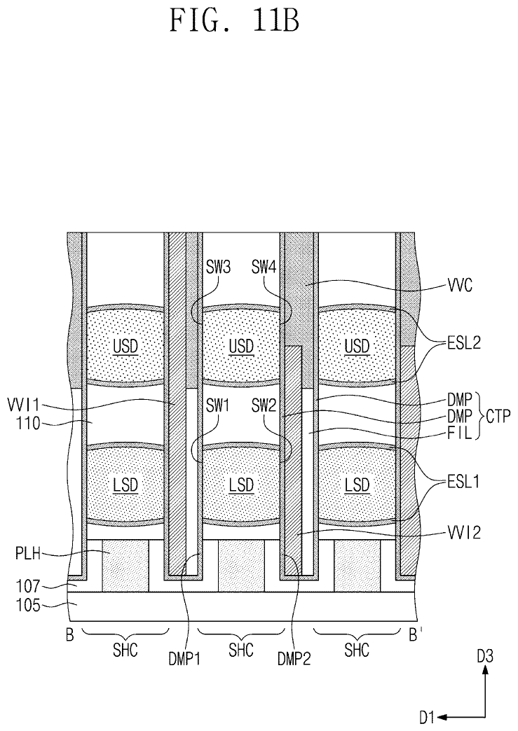

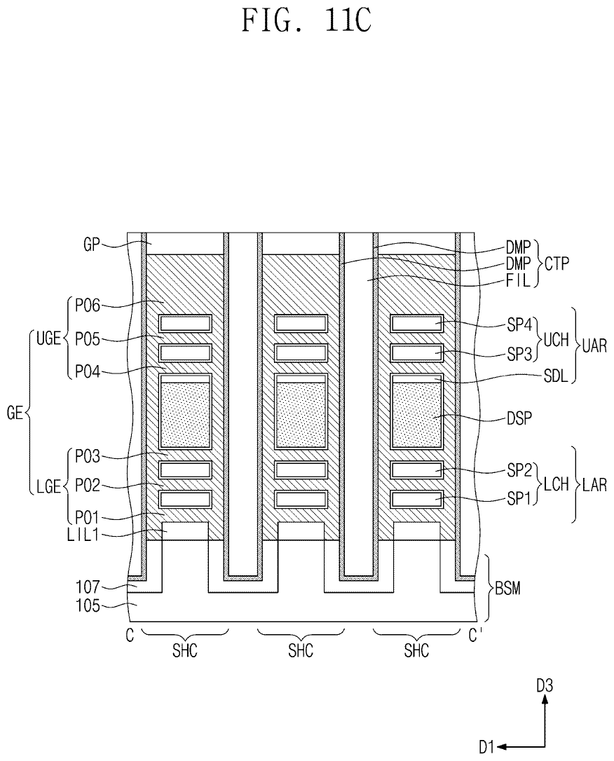

Referring to FIGS. 11A to 11C, the second interlayer insulating layer 120 may be formed on the second etch stop layer ESL2 to fill the recess RS. In some embodiments, the second interlayer insulating layer 120 may include a silicon oxide layer.

The second interlayer insulating layer 120 may be planarized to expose a top surface of the sacrificial pattern PP. The planarization of the second interlayer insulating layer 120 may be performed using an etch-back process or a chemical mechanical polishing (CMP) process. All of the hard mask pattern MP on the sacrificial pattern PP may be removed during the planarization process. As a result, the top surface of the second interlayer insulating layer 120 may be coplanar with the top surface of the sacrificial pattern PP and the top surfaces of the gate spacers GS.

The exposed sacrificial pattern PP may be selectively removed. The removal of the sacrificial pattern PP may include a wet etching process using etching solution capable of selectively etching polysilicon. As a result of the removal of the sacrificial pattern PP, the first and second sacrificial layers SAL1 and SAL2 may be exposed.

An etching process, which is chosen to selectively etch the first and second sacrificial layers SAL1 and SAL2, may be performed to leave the first to fourth semiconductor patterns SP1 to SP4 and the dummy channel pattern DSP and to remove only the first and second sacrificial layers SAL1 and SAL2. The etching process may be chosen to have a high etch rate to silicon germanium. For example, the etching process may be chosen to have a high etch rate to a silicon germanium layer whose germanium concentration is higher than 10 at %.

The gate insulating layer GI may be conformally formed in an empty space, which is formed by removing the sacrificial pattern PP and the first and second sacrificial layers SAL1 and SAL2. The gate electrode GE may be formed on the gate insulating layer GI. The formation of the gate electrode GE may include forming the first to fifth inner electrodes PO1 to PO5 between the first to fourth semiconductor patterns SP1 to SP4 and forming the outer electrode PO6 in a region, which is formed by removing the sacrificial pattern PP.

The gate electrode GE may be recessed to have a reduced height. The gate capping pattern GP may be formed on the recessed gate electrode GE. A planarization process may be performed on the gate capping pattern GP such that a top surface of the gate capping pattern GP is coplanar with the top surface of the second interlayer insulating layer 120.

The vertical via VVI may be formed in the cutting pattern CTP. The vertical via VVI may be formed to vertically extend along one of the paired dam patterns DMP of the cutting pattern CTP. For example, the vertical via VVI may be formed of or include a metallic material that is selected from the group consisting of copper (Cu), aluminum (Al), ruthenium (Ru), cobalt (Co), tungsten (W), and molybdenum (Mo).

The vertical via VVI may be formed between adjacent ones of the single height cells SHC. When viewed in a plan view, the vertical via VVI may have a bar shape extending in the second direction D2 (e.g., see FIG. 3). The vertical via VVI may be spaced apart from the lower and upper source/drain patterns LSD and USD with the dam pattern DMP interposed therebetween.

Referring back to FIG. 11B, the vertical via VVI may include a first vertical via VVI1 and a second vertical via VVI2. A top surface of the first vertical via VVI1 may be coplanar with the top surface of the second interlayer insulating layer 120. A top surface of the second vertical via VVI2 may be lower than the second interlayer insulating layer 120. The contact capping pattern VVC may be formed in a region on the cutting pattern CTP. The contact capping pattern VVC may cover an upper side surface of the first vertical via VVI1. The contact capping pattern VVC may cover the top surface and upper side surface of the second vertical via VVI2.

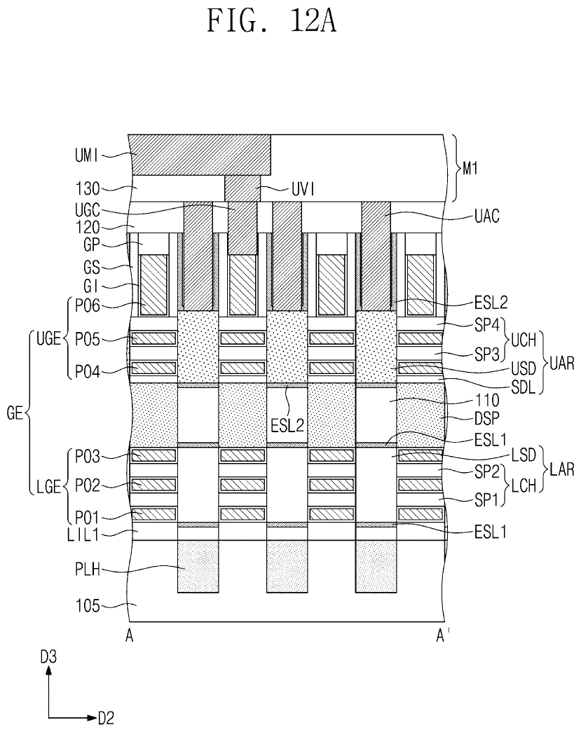

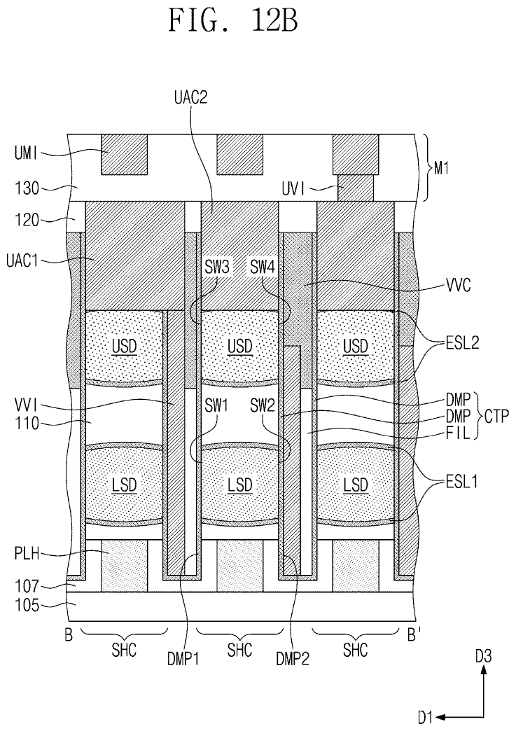

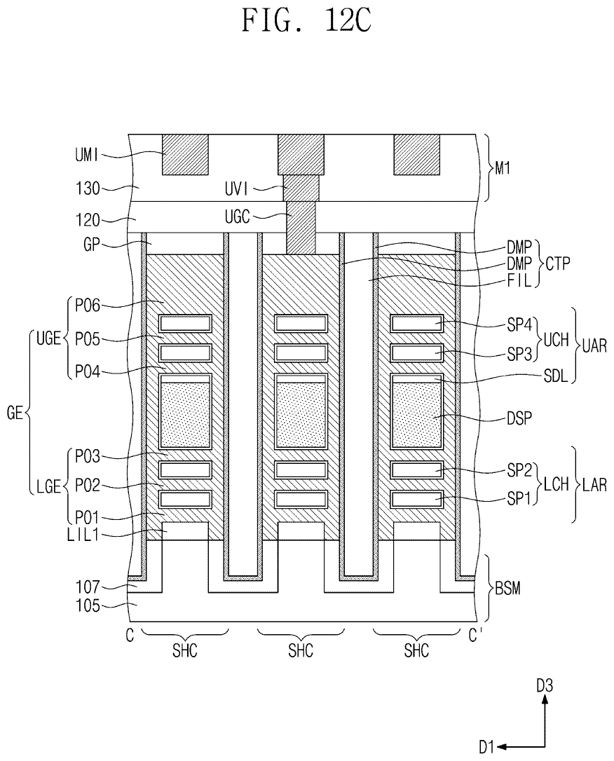

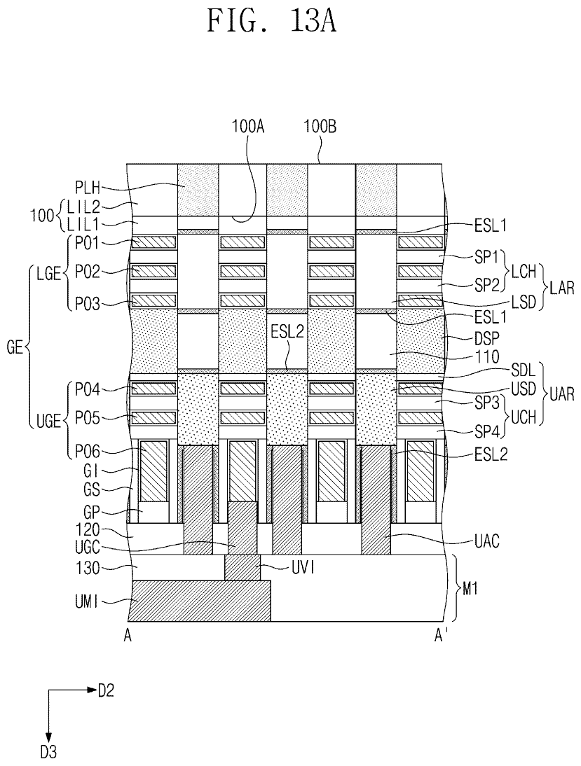

Referring to FIGS. 12A to 12C, the upper active contacts UAC may be formed to penetrate the second interlayer insulating layer 120 and may be coupled (i.e., electrically connected) to the upper source/drain patterns USD, respectively. The upper active contacts UAC may include a first upper active contact UAC1 and a second upper active contact UAC2. The first upper active contact UAC1 may be coupled to the upper source/drain pattern USD as well as the first vertical via VVI1. The second upper active contact UAC2 may be spaced apart from the second vertical via VVI2 by the contact capping pattern VVC.

The upper gate contact UGC may be formed to penetrate the second interlayer insulating layer 120 and the gate capping pattern GP and may be coupled to the gate electrode GE. For example, each of the upper active contact UAC and the upper gate contact UGC may be formed of or include a metallic material that is selected from the group consisting of copper (Cu), aluminum (Al), ruthenium (Ru), cobalt (Co), tungsten (W), and molybdenum (Mo).

The third interlayer insulating layer 130 may be formed on the second interlayer insulating layer 120. The first metal layer M1 including the upper interconnection lines UMI may be formed in the third interlayer insulating layer 130. The upper vias UVI may be formed to electrically connect the first metal layer M1 to the upper gate contacts UGC and the upper active contacts UAC. A BEOL layer including the additional metal layers (e.g., M2, M3, M4, and so forth) may be formed on the first metal layer M1.

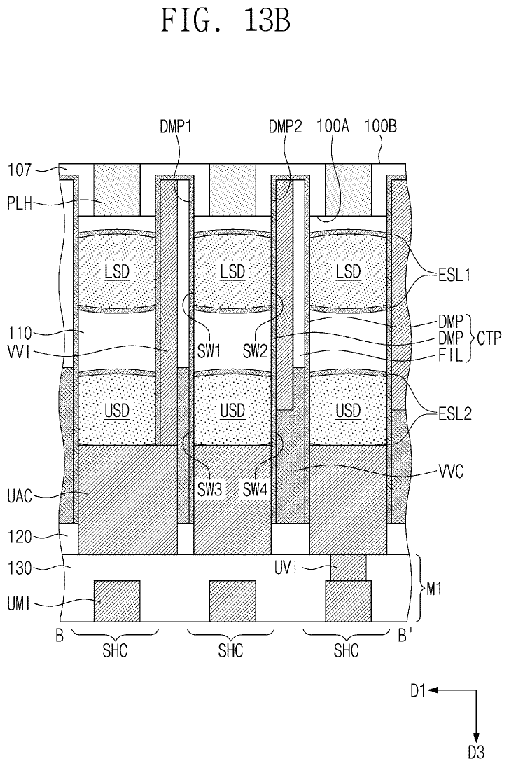

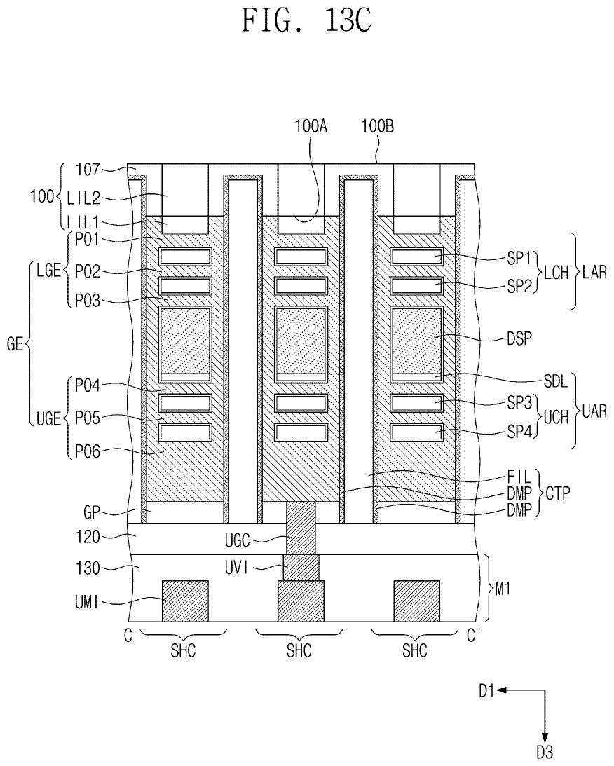

Referring to FIGS. 13A to 13C, the semiconductor substrate 105 may be inverted such that a rear surface of the semiconductor substrate 105 is exposed. The exposed semiconductor substrate 105 may be selectively removed. Accordingly, the sacrificial contact patterns PLH and the first lower insulating layer LIL1 may be exposed.

A second lower insulating layer LIL2 may be formed on the exposed sacrificial contact patterns PLH and the exposed first lower insulating layer LIL1. For example, the second lower insulating layer LIL2 may be formed of or include at least one of silicon-based insulating materials (e.g., silicon oxide, silicon oxynitride, or silicon nitride). In some embodiments, the second lower insulating layer LIL2 may be formed of or include the same material as the device isolation layer 107.

The first and second lower insulating layers LIL1 and LIL2 may constitute the substrate 100. The substrate 100 may include the first surface 100A and the second surface 100B. A planarization process may be performed on the second surface 100B of the substrate 100 to expose top surfaces of the sacrificial contact patterns PLH.

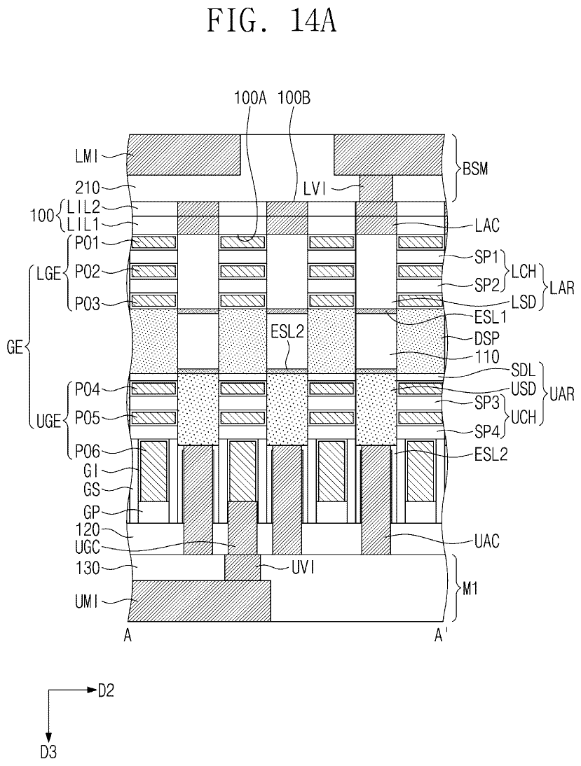

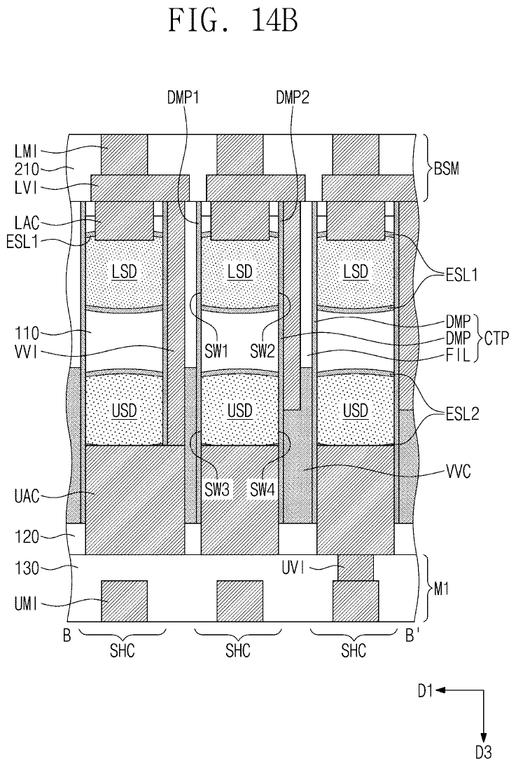

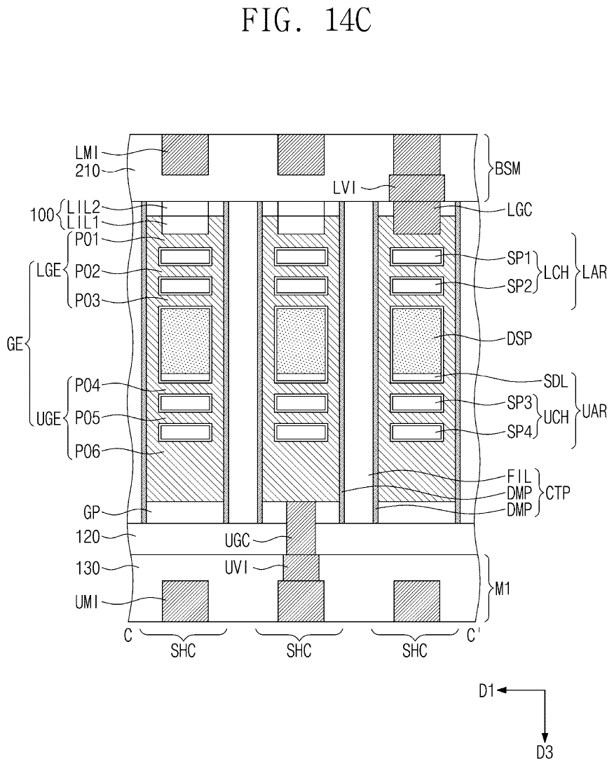

Referring to FIGS. 14A to 14C, the sacrificial contact pattern PLH may be replaced with the lower active contact LAC. In detail, the sacrificial contact pattern PLH may be selectively removed. An etching process may be further performed on a region, which is formed by removing the sacrificial contact pattern PLH, to expose the lower source/drain pattern LSD. The lower active contact LAC may be formed to be coupled (i.e., electrically connected) to the exposed lower source/drain pattern LSD. The lower active contact LAC may be formed in a self-aligned manner using the sacrificial contact pattern PLH.

The lower gate contact LGC may be formed to penetrate the substrate 100 and may be coupled to the gate electrode GE. After the formation of the lower active contact LAC and the lower gate contact LGC, a planarization process may be performed on the second surface 100B of the substrate 100 to expose a top surface of the vertical via VVI.

The lower interlayer insulating layer 210 may be formed on the second surface 100B of the substrate 100. The back-side metal layer BSM may be formed in the lower interlayer insulating layer 210. The back-side metal layer BSM may include the lower interconnection lines LMI. In addition, the lower vias LVI may be formed to electrically connect the back-side metal layer BSM to the lower active contact LAC and the lower gate contact LGC. In some embodiments, the lower via LVI may be formed to connect the lower active contact LAC to the vertical via VVI. Back-side metal layers may be additionally formed on the back-side metal layer BSM. In some embodiments, the back-side metal layers may include a power delivery network. The substrate 100 and the back-side metal layer BSM may then be flipped (e.g., see FIGS. 4A to 4C).

In the following description, an element previously described with reference to FIGS. 3 and 4A to 4C may be identified by the same reference number without repeating an overlapping description thereof.

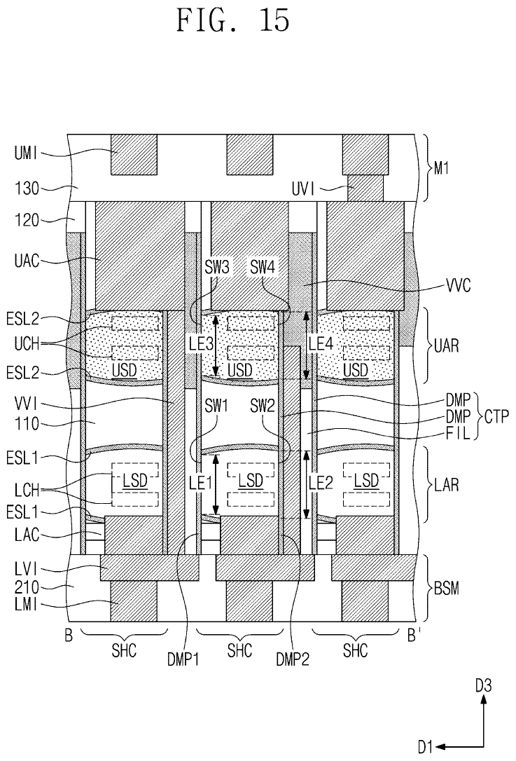

FIG. 15 is a sectional view, which is taken along a line B-B′ of FIG. 3 to illustrate a three-dimensional semiconductor device according to some embodiments of the inventive concepts. Referring to FIG. 15, the cutting pattern CTP may not be provided on a center between adjacent ones of the single height cells SHC and may be slightly offset from the center in a horizontal direction. For example, the cutting pattern CTP may be slightly offset in the first direction D1.

The first and second dam patterns DMP1 and DMP2 may be provided at both sides of the single height cell SHC, respectively. The second dam pattern DMP2 may be closer to the lower and upper channel patterns LCH and UCH than the first dam pattern DMP1. For example, the second dam pattern DMP2 may be overlapped with the upper active contact UAC in the third direction D3, and the first dam pattern DMP1 may be spaced apart from the upper active contact UAC in the first direction D1.

Since the cutting patterns CTP are shifted, the lower source/drain pattern LSD between the first and second dam patterns DMP1 and DMP2 may have an asymmetric shape. For example, the first side surface SW1 of the lower source/drain pattern LSD may have a first length LE1 in the third direction D3, and the second side surface SW2 may have a second length LE2 in the third direction D3. The second length LE2 may be larger than the first length LE1.

Since the cutting patterns CTP are shifted, the upper source/drain pattern USD between the first and second dam patterns DMP1 and DMP2 may have an asymmetric shape. For example, the third side surface SW3 of the upper source/drain pattern USD may have a third length LE3 in the third direction D3, and the fourth side surface SW4 may have a fourth length LE4 in the third direction D3. The fourth length LE4 may be larger than the third length LE3.

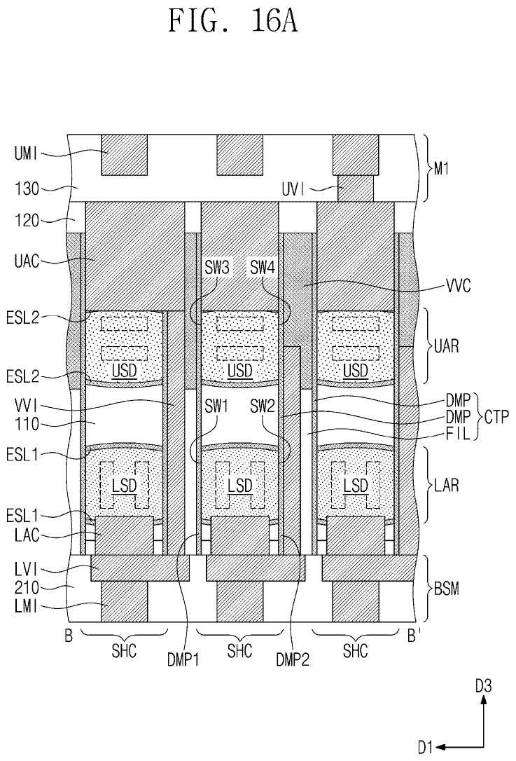

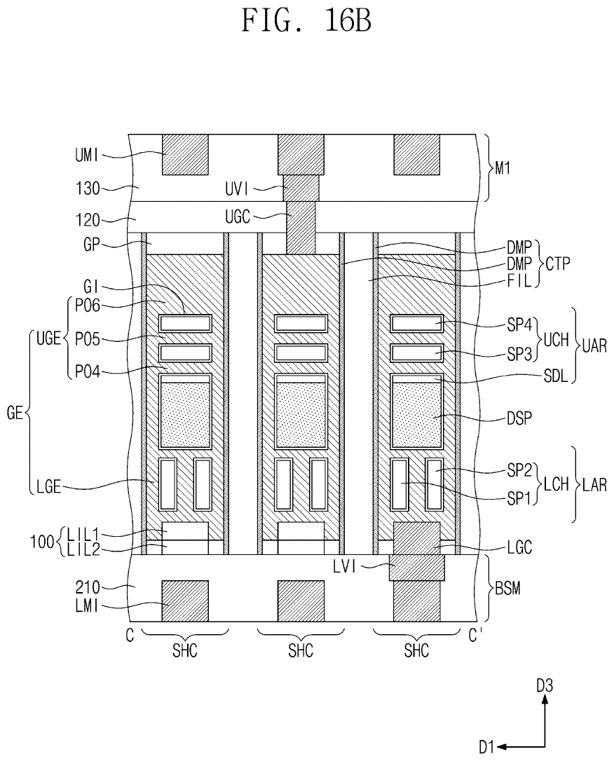

FIGS. 16A and 16B are sectional views, which are respectively taken along lines B-B′ and C-C′ of FIG. 3 to illustrate a three-dimensional semiconductor device according to some embodiments of the inventive concepts. Referring to FIGS. 16A and 16B, the lower channel pattern LCH may have a shape different from the upper channel pattern UCH. For example, the lower channel pattern LCH may include the first and second semiconductor patterns SP1 and SP2, each of which is shaped like a fin (e.g., a vertically erected fin). Each of the first and second semiconductor patterns SP1 and SP2 may be a standing nanosheet. The lower gate electrode LGE may be provided to surround each of the first and second semiconductor patterns SP1 and SP2.

In a three-dimensional semiconductor device according to some embodiments of the inventive concepts, a pair of cutting patterns may be used to define opposite borders of a logic cell. The pair of cutting patterns may prevent lower and upper source/drain patterns from being horizontally expanded to a region beyond the border of the logic cell. Accordingly, it may be possible to reduce a cell height of the logic cell and increase an integration density of the semiconductor device.

According to some embodiments of the inventive concepts, a vertical via, which vertically extends, may be disposed in the cutting pattern. Accordingly, it may be possible to prevent a short circuit between the lower and upper source/drain patterns and the vertical via and improve the reliability characteristics of the semiconductor device.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof.

While example embodiments of the inventive concepts have been particularly shown and described, it will be understood by one of ordinary skill in the art that variations in form and detail may be made therein without departing from the scope of the attached claims.

What is claimed is:

1. A three-dimensional (3D) semiconductor device, comprising:
a substrate including a first surface and a second surface that are opposite to each other;
a lower active region on the first surface of the substrate, the lower active region comprising a lower channel pattern and a lower source/drain pattern that are electrically connected to each other;
an upper active region on the lower active region, the upper active region comprising an upper channel pattern and an upper source/drain pattern that are electrically connected to each other;
a dam pattern that vertically extends from the lower source/drain pattern to the upper source/drain pattern;
a lower active contact electrically connected to the lower source/drain pattern;
an upper active contact electrically connected to the upper source/drain pattern; and
a vertical via that vertically extends along the dam pattern to electrically connect the lower active contact to the upper active contact,
wherein the dam pattern comprises a first dam pattern and a second dam pattern,
wherein the lower source/drain pattern is between the first and second dam patterns, and
wherein the upper source/drain pattern is between the first and second dam patterns.

2. The 3D semiconductor device of claim 1, further comprising a gate electrode on the lower channel pattern and the upper channel pattern,
wherein the gate electrode is between the first and second dam patterns.

3. The 3D semiconductor device of claim 2, wherein each of the lower and upper channel patterns comprises a plurality of semiconductor patterns that are vertically stacked and spaced apart from each other, and
wherein the gate electrode comprises:
a lower gate electrode surrounding the semiconductor patterns of the lower channel pattern; and
an upper gate electrode surrounding the semiconductor patterns of the upper channel pattern.

4. The 3D semiconductor device of claim 1, wherein the lower source/drain pattern comprises a first side surface in contact with the first dam pattern and a second side surface in contact with the second dam pattern, and
wherein a length of the first side surface is different from a length of the second side surface.

5. The 3D semiconductor device of claim 1, wherein the upper source/drain pattern comprises a third side surface in contact with the first dam pattern and a fourth side surface in contact with the second dam pattern, and
wherein a length of the third side surface is different from a length of the fourth side surface.

6. The 3D semiconductor device of claim 1, further comprising:
a first metal layer on the upper active contact; and
a back-side metal layer on the second surface of the substrate.

7. The 3D semiconductor device of claim 1, wherein one of the lower and upper channel patterns comprises a first semiconductor pattern that comprises a vertically erected fin, and
wherein another one of the lower and upper channel patterns comprises a second semiconductor pattern that comprises a nanosheet.

8. The 3D semiconductor device of claim 1, further comprising a dummy channel pattern between the lower channel pattern and the upper channel pattern,
wherein the dummy channel pattern is spaced apart from the lower source/drain pattern and the upper source/drain pattern.

9. The 3D semiconductor device of claim 1, wherein the lower source/drain pattern has a first conductivity type, and
wherein the upper source/drain pattern has a second conductivity type different from the first conductivity type.

10. The 3D semiconductor device of claim 1, wherein the lower active region and the upper active region constitute a logic cell, and
wherein the first and second dam patterns define opposite borders of the logic cell.

11. A three-dimensional (3D) semiconductor device, comprising:
a substrate including a first surface and a second surface that are opposite to each other;
logic cells arranged on the first surface of the substrate in a first direction; and
a cutting pattern that is between adjacent ones of the logic cells and extends in a second direction crossing the first direction,
wherein each of the logic cells comprises:
a lower active region comprising a lower channel pattern and a lower source/drain pattern that are electrically connected to each other;
an upper active region on the lower active region, the upper active region comprising an upper channel pattern and an upper source/drain pattern that are electrically connected to each other; and
a gate electrode on the lower and upper channel patterns,
wherein at least a portion of the cutting pattern extends in the second direction adjacent to the gate electrode, and
wherein the cutting pattern comprises a pair of dam patterns that vertically extend and an insulating gapfill layer that is between the pair of dam patterns.

12. The 3D semiconductor device of claim 11, further comprising:
a lower active contact electrically connected to the lower source/drain pattern;
an upper active contact electrically connected to the upper source/drain pattern; and
a vertical via in the cutting pattern,
wherein the vertical via electrically connects the lower active contact to the upper active contact.

13. The 3D semiconductor device of claim 12, further comprising:
a first metal layer on the upper active contact; and
a back-side metal layer on the second surface of the substrate.

14. The 3D semiconductor device of claim 11, wherein the cutting pattern is configured to prevent the lower and upper source/drain patterns from expanding to a region beyond respective ones of the logic cells.

15. The 3D semiconductor device of claim 11, wherein the cutting pattern comprises a first cutting pattern and a second cutting pattern that define opposite borders of respective ones of the logic cells,
wherein the lower source/drain pattern comprises a first side surface in contact with the first cutting pattern and a second side surface in contact with the second cutting pattern, and
wherein a length of the first side surface is different from a length of the second side surface.

16. A three-dimensional (3D) semiconductor device, comprising:
a lower active region on a logic cell of a substrate, the lower active region comprising a lower channel pattern and a lower source/drain pattern that are electrically connected to each other;
an upper active region on the lower active region, the upper active region comprising an upper channel pattern and an upper source/drain pattern that are electrically connected to each other;
a gate electrode on the lower channel pattern and the upper channel pattern; and
a first cutting pattern and a second cutting pattern that define opposite borders of the logic cell,
wherein the gate electrode is between the first and second cutting patterns,
wherein the lower and upper source/drain patterns are between the first and second cutting patterns,
wherein the lower source/drain pattern comprises a first side surface in contact with the first cutting pattern and a second side surface in contact with the second cutting pattern, and
wherein a length of the first side surface is different from a length of the second side surface.

17. The 3D semiconductor device of claim 16, wherein the upper source/drain pattern comprises a third side surface in contact with the first cutting pattern and a fourth side surface in contact with the second cutting pattern, and
wherein a length of the third side surface is different from a length of the fourth side surface.

18. The 3D semiconductor device of claim 16, further comprising:
a lower active contact electrically connected to the lower source/drain pattern;
an upper active contact electrically connected to the upper source/drain pattern; and
a vertical via that is in the first cutting pattern and vertically extends to electrically connect the lower active contact to the upper active contact.

19. The 3D semiconductor device of claim 18, wherein the substrate includes a first surface and a second surface that are opposite to each other,
wherein the lower active region is on the first surface of the substrate, and
wherein the 3D semiconductor device further comprises:
a first metal layer on the upper active contact; and
a back-side metal layer on the second surface of the substrate.

20. The 3D semiconductor device of claim 16, wherein the first and second cutting patterns are configured to prevent the lower and upper source/drain patterns from expanding to a region beyond the logic cell.
